(19) United States
(12) Patent Application Publication
(10) Pub. No.: US 2026/0341395 A1
(43) Pub. Date: Oct. 29, 2026

(54) PARTIAL DIE REDUNDANCY AND REPLACEMENT SCHEME FOR NONVOLATILE MEMORY DEVICES

(71) Applicant: Sandisk Technologies, Inc., Milpitas, CA (US)

(72) Inventors: Hua-Ling Cynthia Hsu, Fremont, CA (US); Luca Fasoli, Campbell, CA (US); Khin Htoo, Danville, CA (US)

(21) Appl. No.: 19/193,233

(22) Filed: Apr. 29, 2025

(51) Int. Cl. G11C 29/00

(52) U.S. Cl. CPC G11C 29/789; G11C 29/88

(57) ABSTRACT

The present disclosure provides for a partial die redundancy and replacement scheme to recover from defective memory dies. Examples include core dies partitioned into partial dies defining partial die locations, at least one redundancy die partitioned into redundancy partial dies that coincide with the partial die locations, and channels traversing the core dies and the at least one redundancy die. Each channel routes signals to a core die or the at least one redundancy die, and subsets of channels are located in the partial die locations. Examples also include circuitry for replacing a defective partial die by detecting that a partial die is defective, and rerouting a signal from a channel corresponding to the defective partial die to a channel corresponding to a redundancy partial die located in the same partial die location as the defective partial die.

### BACKGROUND

### 1. Field

The present disclosure is related generally to non-volatile memory and, more particularly, to improved memory die recovery scheme for memory devices that provides partial die redundancy and replacement.

### 2. Related Art

Semiconductor memory is widely used in various electronic devices such as cellular telephones, digital cameras, personal digital assistants, medical electronics, mobile computing devices, servers, solid state drives, non-mobile computing devices and other devices. Semiconductor memory may be non-volatile memory or volatile memory. A non-volatile memory allows information to be stored and retained even when the non-volatile memory is not connected to a source of power (e.g., a battery).

Non-volatile memory devices include one or more memory chips having multiple arrays of memory cells. The memory arrays may have associated decoders and circuits for performing read, write, and erase operations. Memory cells within the arrays may be arranged in horizontal rows and vertical columns. Each row may be addressed by a word line, and each column may be addressed by a bit line. Data may be loaded into columns of the array using a series of data busses. Each column may hold a predefined unit of data, for instance, a word encompassing two bytes of information.

In some applications, semiconductor memory is used to store very large amounts of data that are repeatedly accessed (e.g., read) very rapidly. For example, in some machine learning applications, large language models that include a terabyte (or more) of data must be stored in memory and retrieved at a very high data rate. Accordingly, such applications require very high bandwidth and low power.

Currently, high bandwidth volatile memory devices (e.g., DRAM memory devices called “high bandwidth memory” or “HBM”) are used for such applications. Non-volatile memory (e.g., NAND) is significantly less expensive than DRAM, but the bandwidth of conventional NAND memory devices is too low, and the power consumption of conventional NAND memory devices is too high to provide a viable alternative to HBM devices. Therefore, there is a need to provide high bandwidth, low power non-volatile memory.

### SUMMARY

One aspect of the present disclosure is related to a memory package. The memory package includes a plurality of core dies partitioned into a plurality of partial dies defining partial die locations, at least one redundancy die partitioned into a plurality of redundancy partial dies that coincide with the plurality of partial die locations, and a plurality of channels traversing the plurality of core dies and the at least one redundancy die. Each channel of the plurality of channels routes signals to a core die of the plurality of core dies or the at least one redundancy die, and subsets of channels of the plurality of channels are located in the partial die locations. The memory package also includes circuitry for replacing a defective partial die. The circuitry is configured to detect that a partial die of the plurality of partial dies is defective, and reroute a signal from a channel corresponding to the defective partial die to a channel corresponding to a redundancy partial die located in the same partial die location as the defective partial die.

According to another aspect of the present disclosure the plurality of core dies comprises control dies having control circuitry for controlling operations on a memory die.

According to yet another aspect of the present disclosure, the plurality of core dies comprise a plurality of memory dies bonded to the plurality of core dies and each memory die has a plurality of memory blocks with arrays of memory cells.

According to still another aspect of the present disclosure, the plurality of core dies are comprised as a High Bandwidth Flash memory package.

According to another aspect of the present disclosure, the plurality of core dies comprises a plurality of mirror die pairs (mDiPs). Each mirror die pair comprises a pair of core dies bonded together.

According to another aspect of the present disclosure, the at least one redundancy die comprises a pair of redundancy dies bonded together.

According to another aspect of the present disclosure, each of the plurality of core dies and the at least one redundancy die includes a plurality of first through silicon vias (TSVs), a plurality of second TSVs, a plurality of routing elements that connect the plurality of the first TSVs to the plurality of the second TSVs, and a plurality of lateral positions. Each of the plurality of lateral positions comprises one of the first TSVs and one of the second TSVs. Each routing element connects a first TSV in one of the plurality of lateral positions to a second TSV in an adjacent lateral position, where the plurality of first and second TSVs form the plurality of channels.

According to yet another aspect of the present disclosure, a number of first TSVs in the plurality of first TSVs in a respective core die of the plurality of core dies is equal to a number of channels, and the number of channels is based on a number of the plurality of core dies and the at least one redundancy die.

According to still another aspect of the present disclosure, the at least one redundancy die includes a plurality of switching circuits connected to the plurality of second TSVs of the at least one redundancy die.

Another aspect of the present disclosure is related to method of operating a memory package. The method includes preparing a core memory die stack that includes a plurality of core dies partitioned into a plurality of partial dies defining partial die locations, a redundancy die partitioned into a plurality of redundancy partial dies that coincide with the partial die locations, and a plurality of channels traversing the core memory die stack that route signals to a core die or the redundancy die. The method also includes detecting a defective partial die of the plurality of partial dies, and rerouting one or more control signals from one or more channels corresponding to the defective partial die to one or more channels corresponding to a redundancy partial die located in the same partial die location as the defective partial die.

According to another aspect of the present disclosure, rerouting the one or more control signals includes disabling the one or more channels corresponding to the defective partial die, and routing the one or more control signals to the one or more channels of the redundancy partial die.

According to another aspect of the present disclosure, rerouting the one or more control signals is based on a mapping of channels corresponding to the plurality of core dies to channels corresponding to the redundancy die.

According to another aspect of the present disclosure, the one or more control signals comprises a plurality of control signals routed over the one or more channels, where a number of channels in the one or more channels is equal to a number of bits of the one or more control signals.

According to yet another aspect of the present disclosure, the plurality of control signals comprises chip select (CS) control signals, command/address (CA) control signals, and clock signals.

According to still another aspect of the present disclosure, data (DQ) control signals of the defective partial die are routed over one or more channels corresponding to the defective partial die.

According to yet another aspect of the present disclosure, the plurality of control signals comprises data (DQ) controls signal.

According to another aspect of the present disclosure, the one or more control signals comprises X1 mode control signals.

Yet another aspect of the present disclosure is related to a computing system that includes a processing unit and a plurality of non-volatile memory packages that are in electrical communication with the processing unit. At least one of the non-volatile memory packages includes a plurality of memory dies partitioned into a plurality of partial dies defining partial die locations, at least one redundancy die partitioned into a plurality of redundancy partial dies that coincide with the partial die locations, and a plurality of channels traversing the plurality of core dies and the at least one redundancy die. Each channel of the plurality of channels routes signals to a core die of the plurality of core dies or the at least one redundancy die, and subsets of channels of the plurality of channels are located in the partial die locations. The at least one of the non-volatile memory packages also includes circuitry for replacing a defective partial die. The circuitry is configured to detect that a partial die of the plurality of partial dies is defective, and reroute a signal from a channel corresponding to the defective partial die to a channel corresponding to a redundancy partial die located in the same partial die location as the defective partial die.

According to another aspect of the present disclosure, the at least one of the non-volatile memory packages is a High Bandwidth Flash memory package.

According to another aspect of the present disclosure, rerouting the signal includes disabling the channel corresponding to the defective partial die, and routing the control signal to the channel of the redundancy partial die.

### BRIEF DESCRIPTION OF THE DRAWINGS

These and other features and advantages of the subject disclosure will become more readily appreciated when considered in connection with the following description of the presently preferred embodiments, appended claims and accompanying drawings, in which:

FIG. 1 is a block diagram depicting one embodiment of a storage system;

FIG. 2A is a block diagram of one embodiment of a memory die;

FIG. 2B is a block diagram of one embodiment of an integrated memory assembly;

FIGS. 3A and 3B depict different embodiments of integrated memory assemblies;

FIG. 4A is a perspective view of a portion of one embodiment of a monolithic three dimensional memory structure;

FIG. 4B is a block diagram of one embodiment of a memory structure having four planes;

FIG. 4C depicts a top view of a portion of one embodiment of a block of memory cells;

FIG. 4D depicts a cross sectional view of a portion of one embodiment of a block of memory cells;

FIG. 4E depicts a cross sectional view of a portion of one embodiment of a block of memory cells;

FIG. 4F is a cross sectional view of one embodiment of a vertical column of memory cells;

FIG. 4G is a schematic of a plurality of NAND strings in multiple regions of a same block;

FIG. 5 is a schematic view of an exemplary computing system constructed according to an exemplary embodiment of the present disclosure;

FIG. 6 is a schematic view of an exemplary non-volatile memory package according to an exemplary embodiment of the present disclosure;

FIG. 7A is a perspective top down view of a schematic representation of an example memory package;

FIG. 7B is a block diagram of an example configuration of through silicon vias;

FIG. 8 depicts a correspondence of channels to core dies within the memory package of FIG. 7A;

FIG. 9 illustrates a schematic block diagram of cross-sectional view of a portion of the memory package of FIG. 7A;

FIG. 10 depicts a schematic view of an example memory package that can be used to implement the partial die replacement and recover schemes according to examples disclosed herein;

FIG. 11 depicts an example control scheme that can be used to replace defective partial dies according to examples of the present disclosure;

FIG. 12 illustrates a schematic block diagram of a portion of the memory package of FIG. 10 in accordance with some examples disclosed herein; and

FIG. 13 illustrates a schematic diagram of a redundancy die that may be implemented to route control signals through original channels, in accordance with an example of the present disclosure.

FIG. 14 depicts a flow chart depicting steps of performing a quarter die replacement according to an embodiment of the present disclosure.

### DETAILED DESCRIPTION OF THE ENABLING EMBODIMENT

Technology is described for improving memory die error recovery through a partial die redundancy and replacement scheme to recover from memory die yield and defect loss. Examples disclosed herein provide for a memory package that includes a plurality of core dies partitioned into a plurality of partial dies (e.g., quarter dies in particular examples) defining partial die locations and at least one redundancy die partitioned into a plurality of redundancy partial dies that coincide with the partial die locations. A plurality of channels are provided that traverse the plurality of core dies and the at least one redundancy die. Each channel routes signals to a core die or the at least one redundancy die, and subsets of channels are located in the partial die locations. The memory package can be configured to detect a defective partial die and replace the defective partial die by rerouting one or more control signal from one or more channels corresponding to the defective partial die to one or more channels corresponding to a redundancy partial die located in the same partial die location as the defective partial die. Once replaced, the recovered memory package can be used in computing systems. These techniques are discussed in further detail below.

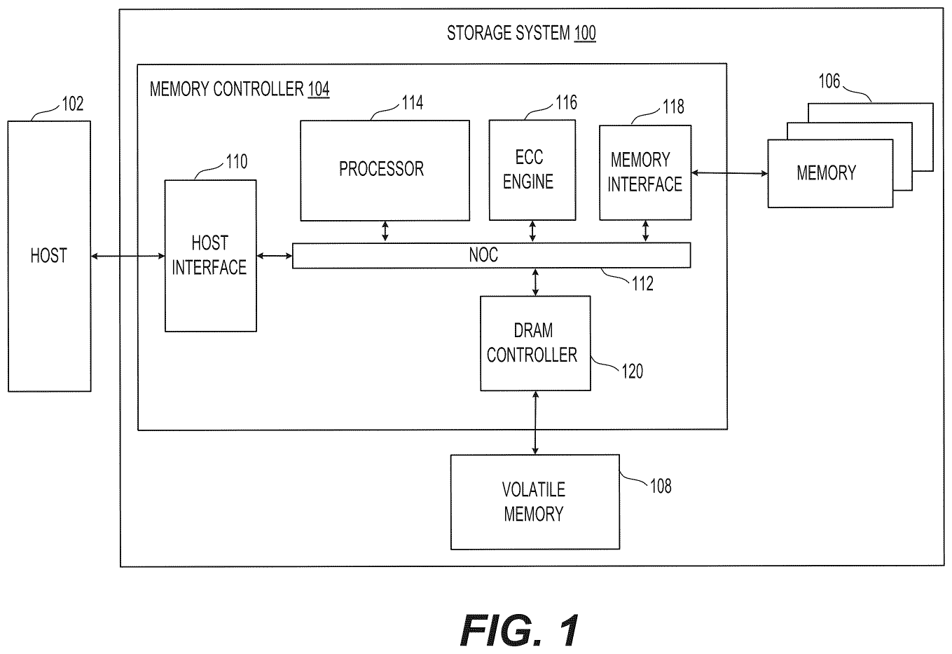

FIG. 1 is a block diagram of one embodiment of a storage system 100 that implements the proposed technology described herein. In one embodiment, the storage system 100 is a solid state drive (“SSD”). The storage system 100 also can be a memory card, a USB drive, or any other type of storage system. In other words, the proposed technology is not limited to any one type of memory system.

The storage system 100 is connected to a host 102, which can be a computer; server; electronic device (e.g., smart phone, tablet or other mobile device); appliance; or another apparatus that uses memory and has data processing capabilities. In some embodiments, the host 102 is separate from, but connected to, the storage system 100. In other embodiments, the storage system 100 is embedded within the host 102.

The components of the storage system 100 depicted in FIG. 1 are electrical circuits. The storage system 100 includes a memory controller 104 connected to non-volatile memory 106 and local high speed volatile memory 108 (e.g., DRAM). A local high speed volatile memory 108 is used by memory controller 104 to perform certain functions. For example, the local high speed volatile memory 108 stores logical to physical address translation tables (“L2P tables”).

The memory controller 104 includes a host interface 110 that is connected to and in communication with the host 102. In one embodiment, a host interface 110 implements an NVM Express (NVMe) over PCI Express (PCIe). Other interfaces can also be used, such as SCSI, SATA, etc. The host interface 110 also is connected to a network-on-chip (NOC) 112.

An NOC is a communication subsystem on an integrated circuit. The NOC's can span synchronous and asynchronous clock domains or use un-clocked asynchronous logic. NOC technology applies networking theory and methods to on-chip communications and brings notable improvements over conventional bus and crossbar interconnections. The NOC improves the scalability of systems on a chip (SoC) and the power efficiency of complex SoCs compared to other designs.

The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, the NOC 112 can be replaced by a bus.

Connected to and in communication with NOC 112 is a processor 114, an ECC engine 116, a memory interface 118, and a DRAM controller 120. The DRAM controller 120 is used to operate and communicate with local high speed volatile memory 108 (e.g., DRAM). In other embodiments, the local high speed volatile memory 108 can be SRAM or another type of volatile memory.

In operation, the processor 114 performs the various controller memory operations, such as programming, erasing, reading, and memory management processes. In one embodiment, the processor 114 is programmed by firmware. In other embodiments, the processor 114 is a custom and dedicated hardware circuit without any software. The processor 114 also implements a translation module, as a software/firmware process or as a dedicated hardware circuit.

In many systems, the non-volatile memory is addressed internally to the storage system using physical addresses associated with one or more memory dies. However, the host system will use logical addresses to address the various memory locations. This enables the host to assign data to consecutive logical addresses, while the storage system is free to store the data as it wishes among the locations of the one or more memory dies. To implement this system, the memory controller 104 (e.g., the translation module) performs address translation between the logical addresses used by the host and the physical addresses used by the memory dies.

One example implementation is to maintain tables (i.e., the L2P tables referenced above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 108 cannot hold all of the L2P tables. In such a case, the entire set of L2P tables are stored in non-volatile memory 106 and a subset of the L2P tables are cached (L2P cache) in the local high speed volatile memory 108.

The ECC engine 116 performs error correction services. For example, the ECC engine 116 performs data encoding and decoding, as per an implemented ECC technique. In one embodiment, the ECC engine 116 is an electrical circuit programmed by software. For example, the ECC engine 116 can be a processor that can be programmed. In other embodiments, the ECC engine 116 is a custom and dedicated hardware circuit without any software. In another embodiment, the function of ECC engine 116 is implemented by the processor 114.

The memory interface 118 communicates with the non-volatile memory 106. In one embodiment, the memory interface provides a Toggle Mode interface. However, other interfaces also can be used. In some example implementations, the memory interface 118 (or another portion of the controller 104) implements a scheduler and buffer for transmitting data to and receiving data from one or more memory die.

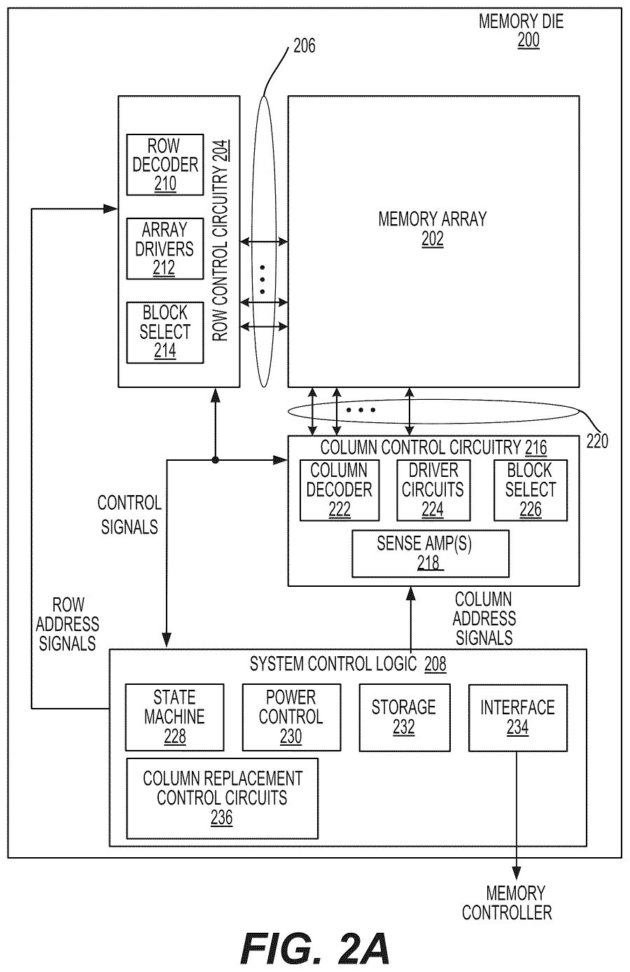

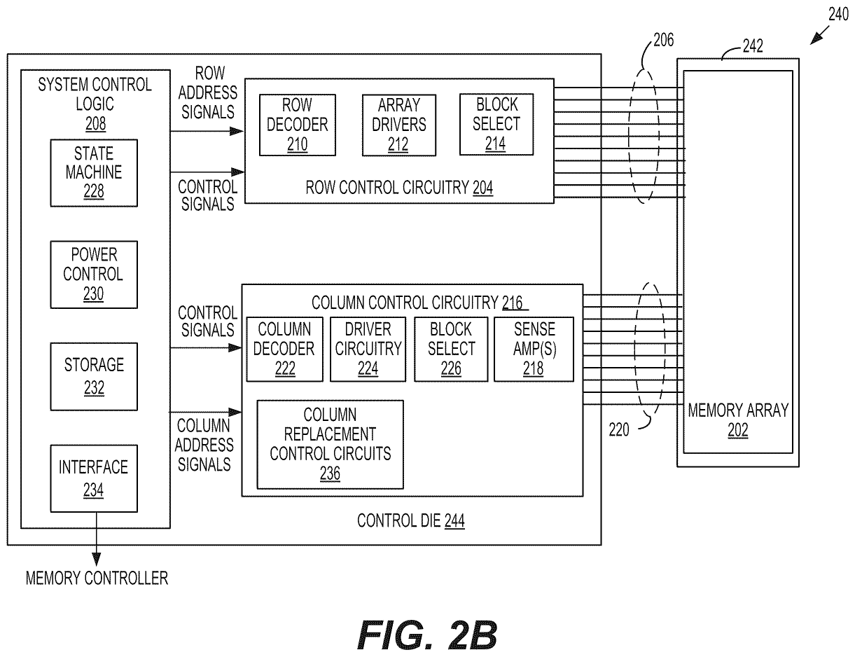

In one embodiment, the non-volatile memory 106 includes one or more memory die. FIG. 2A is a functional block diagrams of one embodiment of a memory die 200 that includes the non-volatile memory 106. Each of the one or more memory dies of non-volatile memory 106 can be implemented as the memory die 200 of FIG. 2A. The components depicted in FIG. 2A are electrical circuits.

The memory die 200 includes a memory array 202 that can include non-volatile memory cells, as described in further detail below. The memory array 202 includes a plurality of layers of word lines that are organized as rows, and a plurality of layers of bit lines that are organized as columns. However, other orientations can also be implemented.

The memory die 200 also includes row control circuitry 204, whose outputs 206 are connected to respective word lines of the memory array 202. In operation, the row control circuitry 204 receives a group of M row address signals and one or more various control signals from a system control logic circuit 208 and may include such circuits as row decoders 210, array terminal drivers 212, and block select circuitry 214 for both reading and writing (programming) operations.

The row control circuitry 204 also may include read/write circuitry. The memory die 200 also includes column control circuitry 216 including sense amplifier(s) 218 whose input/outputs 220 are connected to respective bit lines of the memory array 202. Although only a single block is shown for memory array 202, the memory die 200 can include multiple arrays that can be individually accessed.

The column control circuitry 216 receives a group of N column address signals and one or more various control signals from system control logic 208. The column control circuitry 216 may also include such circuits as column decoders 222; array terminal receivers or driver circuits 224; block select circuitry 226; read/write circuitry; and I/O multiplexers.

The system control logic 208 receives data and commands from memory controller 104 (FIG. 1) and provides output data and status to host 102. In some embodiments, the system control logic 208, which includes one or more electrical circuits, includes a state machine 228 that provides die-level control of memory operations. In one embodiment, the state machine 228 is programmable by software. In other embodiments, the state machine 228 does not use software and is completely implemented in hardware (e.g., electrical circuits). In another embodiment, the state machine 228 is replaced by a micro-controller or microprocessor, either on or off the memory chip.

The system control logic 208 also can include a power control module 230 that controls the power and voltages supplied to the rows and columns of memory structure 202 during memory operations and may include charge pumps and regulator circuits for creating regulating voltages. The system control logic 208 also includes storage 232 (e.g., RAM, registers, latches, etc.), which may be used to store parameters for operating memory array 202.

In operation, commands and data are transferred between the memory controller 104 and the memory die 200 via a memory controller interface 234 (also referred to as a “communication interface”). The memory controller interface 234 is an electrical interface for communicating with memory controller 104. Examples of the memory controller interface 234 include a Toggle Mode Interface and an Open NAND Flash Interface (ONFI). Other I/O interfaces can also be used in other embodiments.

In an embodiment, the system control logic 208 also includes column replacement control circuits 236, described in more detail below.

In some embodiments, all elements of the memory die 200, including the system control logic 208, can be formed as part of a single die. In other embodiments, some or all of the system control logic 208 can be formed on a different die.

In one embodiment, the memory structure 202 comprises a three-dimensional memory array of non-volatile memory cells in which multiple memory levels are formed above a single substrate, such as a wafer. The memory structure 202 may include any type of non-volatile memory that are monolithically formed in one or more physical levels of memory cells having an active area disposed above a silicon (or other type of) substrate. In one example, the non-volatile memory cells include charge-trapping layers and are arranged in a plurality of vertical NAND strings.

In another embodiment, the memory structure 202 includes a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. For example, suitable technologies for the memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of memory structure 202 include two dimensional arrays, three dimensional arrays, cross-point arrays, stacked two dimensional arrays, vertical bit line arrays, and the like. One example of a ReRAM cross-point memory includes reversible resistance-switching elements arranged in cross-point arrays accessed by X lines and Y lines (e.g., word lines and bit lines).

In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, and the ferromagnetic layers are separated by a thin insulating layer. One of the two ferromagnetic layers is a permanent magnet that is set to a particular polarity, and the other ferromagnetic layer's magnetization can be changed to match that of an external field to store memory. The memory array may be built from a grid of such memory cells. In one embodiment, for programming, each memory cell lies between a pair of write lines that are arranged at right angles to each other, parallel to the cell, one above and one below the cell. When current is passed through the write lines, an induced magnetic field is created. MRAM based memory embodiments will be discussed in more detail below.

Phase change memory (PCM) exploits the unique behavior of chalcogenide glass. One embodiment uses a GeTe—Sb₂Te₃ super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

The technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) the memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202. However, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to system control logic 208, reduced availability of area can limit the available functions that can be implemented on-chip. Consequently, a basic trade-off in the design of a memory die for the storage system 100 may be the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based.

Elements such as the sense amplifier circuits, charge pumps, logic elements in a state machine, and other peripheral circuitry in the system control logic 208 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto a separately formed die that is then bonded together with another die. More specifically, the memory structure 202 can be formed on one die (referred to as the memory die) and some or all of the peripheral circuitry elements, including one or more control circuits, can be formed on a separate die (referred to as the control die). A memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology.

For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array.

The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 240. One or more integrated memory assemblies 240 may be used to implement the non-volatile memory 106 of storage system 100.

The integrated memory assembly 240 includes two types of semiconductor die (or more succinctly, “die”). The memory die 242 includes the memory structure 202 with the non-volatile memory cells. A control die 244 includes control circuitry 208, 216, and 204 (as described above). In some embodiments, the control die 244 is configured to connect to the memory structure 202 in the memory die 242. In some embodiments, the memory die 242 and control die 244 are bonded together.

FIG. 2B shows an example of the peripheral circuitry, including control circuits, formed in a peripheral circuit or control die 244 coupled to memory structure 202 formed in memory die 242. Common components are labelled similarly to FIG. 2A. The system control logic 208, the row control circuitry 204, and the column control circuitry 216 are located in the control die 244. In some embodiments, all or a portion of column control circuitry 216 and all or a portion of the row control circuitry 204 are located on memory die 242. In some embodiments, some of the circuitry in the system control logic 208 is located on the memory die 242.

The system control logic 208, the row control circuitry 204, and the column control circuitry 216 may be formed by a common process (e.g., CMOS process), so that adding elements and functions, such as the ECC controller, more typically found on a memory controller 104 may require few or no additional process steps, i.e., the same process steps used to fabricate controller 104 may also be used to fabricate the system control logic 208, the row control circuitry 204, and the column control circuitry 216.

Thus, while moving such circuits from a die such as the memory die 242 may reduce the number of steps needed to fabricate such a die, adding such circuits to a die such as control die 244 may not require many additional process steps. The control die 244 also could be referred to as a CMOS die, due to the use of CMOS technology to implement some or all of the control circuitry 204, 208, 216.

FIG. 2B shows column control circuitry 216, including the sense amplifier(s) 218, on control die 244 coupled to memory structure 202 on memory die 242 through electrical paths 220. The electrical paths 220 may provide an electrical connection between the column decoder 222, the driver circuitry 224, the block select 226, and the bit lines of the memory structure 202. In an embodiment, the column control circuitry 216 also includes column replacement control circuits 236, which are described in more detail below.

Electrical paths may extend from the column control circuitry 216 in the control die 244 through pads on the control die 244 that are bonded to corresponding pads of the memory die 242, which are connected to the bit lines of the memory structure 202. Each bit line of the memory structure 202 may have a corresponding one of the electrical paths 220, including a pair of bond pads, which connects to the column control circuitry 216.

Similarly, the row control circuitry 204, including the row decoder 210, the array drivers 212, and the block select 214 are coupled to the memory structure 202 through electrical paths 206. Each of the electrical paths 206 may correspond to a data containing word line, a dummy word line, or a select gate line. Additional electrical paths may also be provided between control die 244 and memory die 242.

For purposes of this document, the phrases “a control circuit,” “control circuitry,” or “one or more control circuits” can include any one of or any combination of the memory controller 104; the state machine 228; all or a portion of the system control logic 208; all or a portion of row control circuitry 204; all or a portion of column control circuitry 216; a microcontroller; a microprocessor; and/or other similar functioned circuits.

The control circuit can include hardware only or a combination of hardware and software (including firmware). For example, one or more controllers programmed by firmware to perform the functions described herein is one example of a control circuit. A control circuit can include a processor, FGA, ASIC, integrated circuit, or other type of circuit.

In some embodiments, there is more than one control die 244 and more than one memory die 242 in an integrated memory assembly 240. In some embodiments, the integrated memory assembly 240 includes a stack of multiple control dies 244 and multiple memory dies 242.

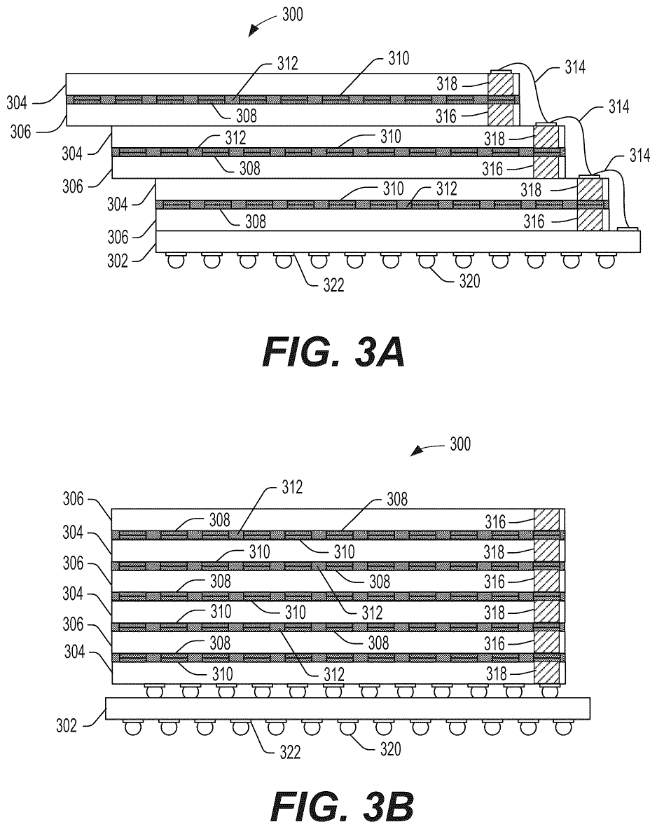

FIG. 3A depicts a side view of an embodiment of an integrated memory assembly 300 stacked on a substrate 302 (e.g., a stack including control die 304 and memory die 306). In this embodiment, the integrated memory assembly 300 has three control die 304 and three memory die 306. In some embodiments, there are more than three memory die 306 and more than three control die 304.

Each control die 304 is affixed (e.g., bonded) to at least one memory die 306. Some of the bond pads 308/310 are depicted, although there may be many more bond pads. A space between two die 306, 304 that are bonded together is filled with a solid layer 312, which may be formed from epoxy or other resin or polymer. This solid layer 312 protects the electrical connections between the die 306, 304 and further secures the die together. Various materials may be used as solid layer 312, but in some embodiments, it may be Hysol epoxy resin from Henkel Corp., having offices in California, USA.

Integrated memory assembly 300 may for example be stacked with a stepped offset, leaving the bond pads at each level uncovered and accessible from above. Wire bonds 314 connected to the bond pads connect control die 304 to substrate 302. A number of such wire bonds may be formed across the width of each control die 304 (i.e., into the page of FIG. 3A).

A memory die through silicon via (TSV) 316 may be used to route signals through each memory die 306. A control die TSV 318 may be used to route signals through each control die 304. The TSVs 316, 318 may be formed before, during or after formation of the integrated circuits in semiconductor die 306, 304. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, Solder balls 320 optionally may be affixed to contact pads 322 on a lower surface of substrate 302. Solder balls 320 may be used to couple integrated memory assembly 300 electrically and mechanically to a host device such as a printed circuit board. Solder balls 320 may be omitted where the integrated memory assembly 300 is to be used as an LGA package. Solder balls 320 may form a part of an interface between integrated memory assembly 300 and memory controller 104 (FIG. 1).

FIG. 3B depicts a side view of another embodiment of an integrated memory assembly 300 stacked on a substrate 302. The integrated memory assembly 300 of FIG. 3B has three control die 304 and three memory die 306. In some embodiments, there are many more than three memory die 306 and many more than three control die 304. In this example, each control die 304 is bonded to at least one memory die 306. Optionally, a control die 304 may be bonded to two or more memory die 306.

Some of the bond pads 308, 310 are depicted, but there may be many more bond pads than are illustrated. A space between two die 306, 304 that are bonded together is filled with a solid layer 312, which may be formed from epoxy or other resin or polymer. In contrast to the example in FIG. 3A, the integrated memory assembly 300 of FIG. 3B does not have a stepped offset. A memory die TSV 316 may be used to route signals through each memory die 306. A control die TSV 318 may be used to route signals through each control die 304.

As has been briefly discussed above, control die 304 and memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process.

In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension.

As has been briefly discussed above, the control die 304 and the memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat also may be applied. In embodiments using cu-to-cu bonding, the bond pads may be about 5 μm square and spaced from each other with a pitch of 5 μm to 5 μm. Although this process is referred to herein as cu-to-cu bonding, this term also may apply even where the bond pads are formed of materials other than copper. When the area of bond pads is small, it may be difficult to bond the semiconductor die together. The size of and pitch between bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on a surface of the control die 304 and the memory die 306. Where no such film is initially provided, a space between the die may be under filled with an epoxy or other resin or polymer. The under-fill material may be applied as a liquid which then hardens into a solid layer. This under-fill step protects the electrical connections between control die 304 and memory die 306, and further secures the die together. Various materials may be used as under-fill material, such as Hysol epoxy resin from Henkel Corp., having offices in California, U.S.A.

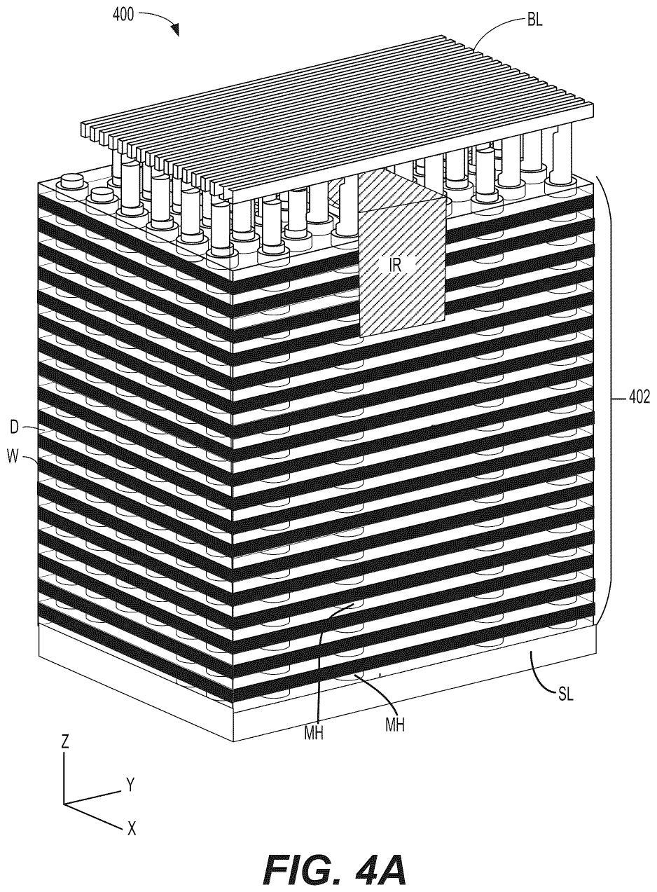

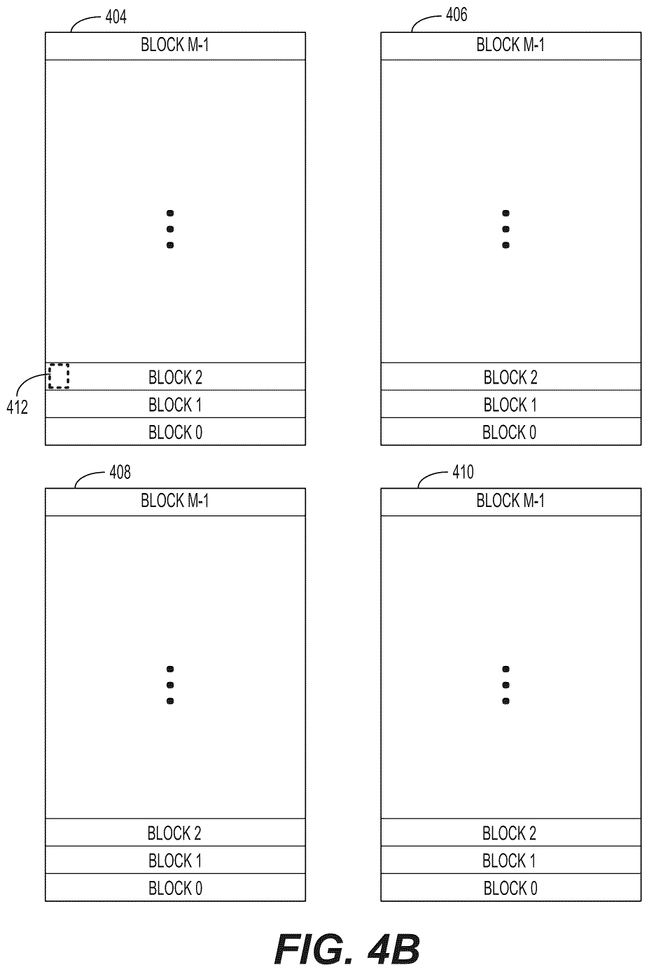

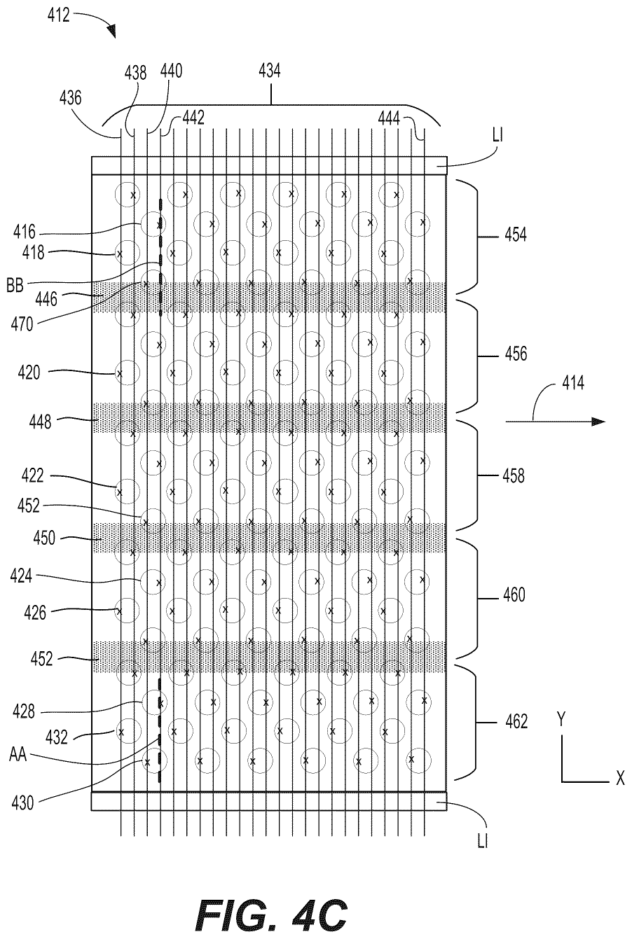

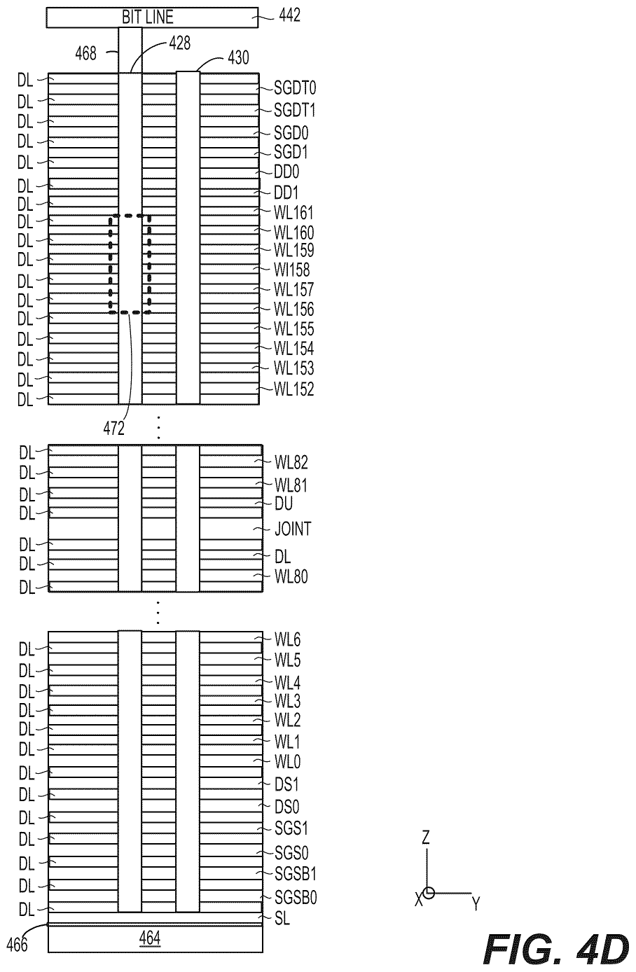

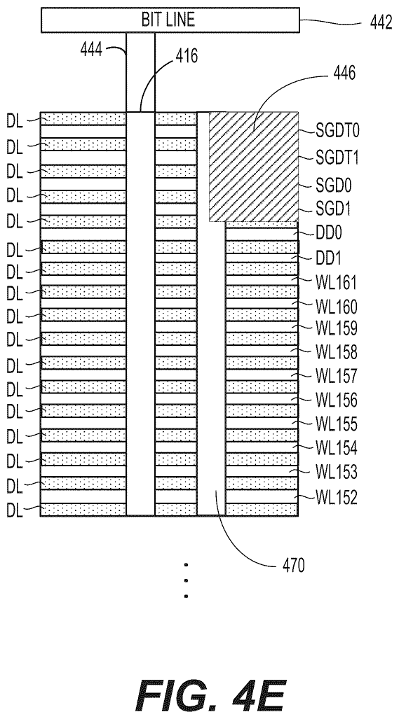

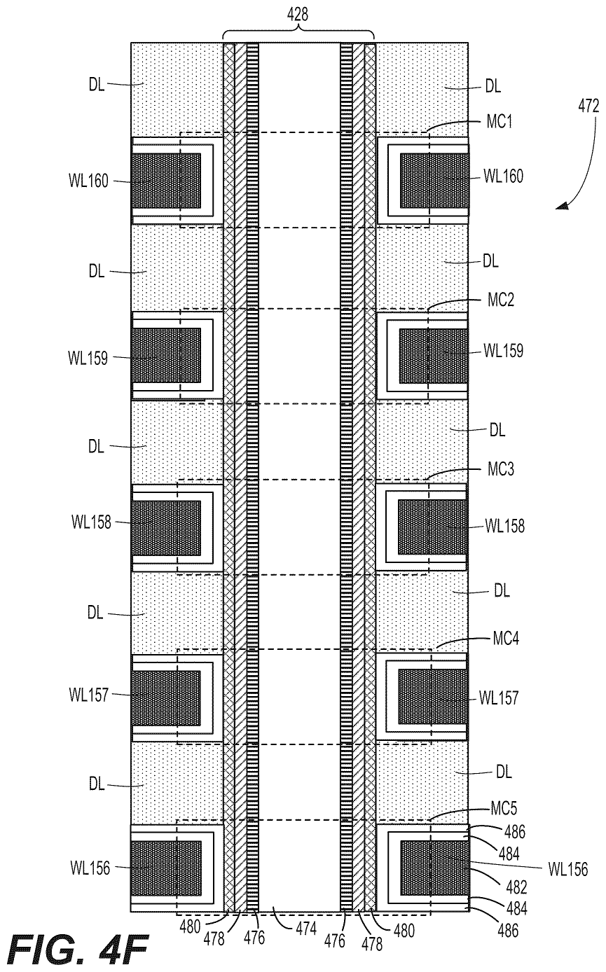

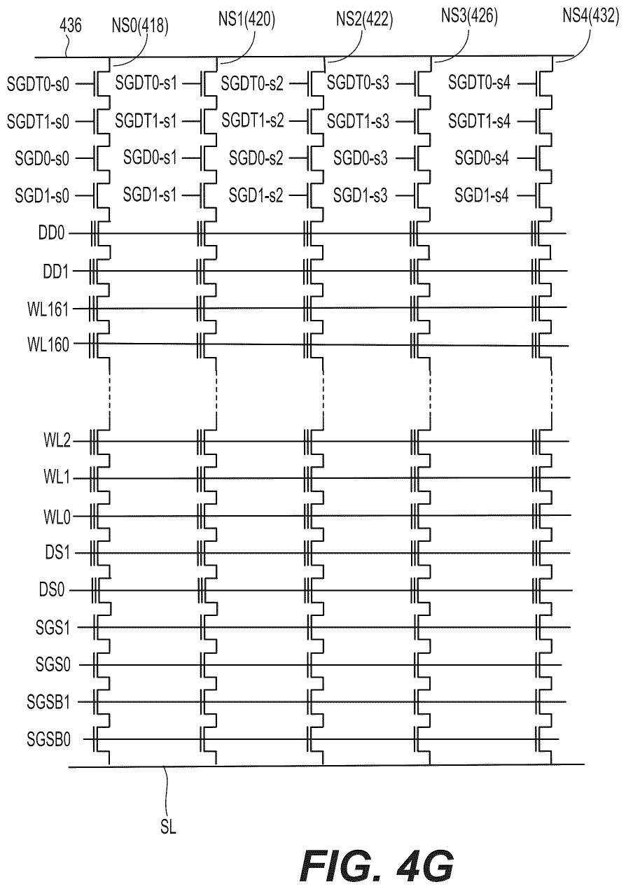

FIG. 4A is a perspective view of a portion of one example embodiment of a monolithic three dimensional memory array/structure included in memory structure 202, which includes a plurality non-volatile memory cells arranged as vertical NAND strings. For example, FIG. 4A shows a portion 400 of one block of memory. The structure depicted includes a set of bit lines BL positioned above a stack 402 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements.

As will be explained below, in one embodiment the alternating dielectric layers and conductive layers are divided into, for example, four or five (or a different number of) regions by isolation regions IR. FIG. 4A shows one isolation region IR separating two regions. Below the alternating dielectric layers and word line layers is a common source line layer SL. Memory holes are formed in the stack of alternating dielectric layers and conductive layers. For example, one of the memory holes is marked as MH. Note that in FIG. 4A, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells.

The non-volatile memory cells are arranged in memory holes, and each memory cell can store one or more bits of data, e.g., up to five bits of data per memory cell. More details of the three dimensional monolithic memory array that comprises memory structure 202 is provided below.

FIG. 4B is a block diagram explaining one example organization of memory structure 202, which is divided into four planes 404, 406, 408 and 410. Each plane is then divided into M blocks. In one example, each plane has about 2,000 blocks (“Block 0” to “Block M-1” with M being 2,000). However, different numbers of blocks and planes can also be used.

In one embodiment, a block of memory cells is a unit of erase. That is, all memory cells of a block are erased together. In other embodiments, the blocks can be divided into sub-blocks, each of which includes a plurality of word lines, and the sub-blocks can be the unit of erase. Memory cells also can be grouped into blocks for other reasons, such as to organize the memory structure to enable the signaling and selection circuits.

In some embodiments, a block represents groups of connected memory cells as the memory cells of a block share a common set of word lines. For example, the word lines for a block are all connected to all of the vertical NAND strings for that respective block. Although FIG. 4B shows four planes, each of which includes a plurality of blocks, more or fewer than four planes can be implemented in the memory structure 202. In some embodiments, the memory structure includes eight planes.

Each block typically is divided into one or more pages, with each page being a unit of programming/writing and a unit of reading. Other units of programming also can be used. In an embodiment, one or more pages of data are typically stored in one row of memory cells. For example, one or more pages of data may be stored in memory cells connected to a common word line. In an embodiment, a page includes data stored in all memory cells connected to a common word line within the block.

FIGS. 4C-4G depict an example three dimensional (“3D”) NAND structure that corresponds to the structure of FIG. 4A and can be used to implement the memory structure 202 of FIGS. 2A and 2B. FIG. 4C is a block diagram that depicts a top view of a portion 412 of Block 2 of plane 404. As can be seen from FIG. 4C, the block depicted in FIG. 4C extends in the direction of 414. In one embodiment, the memory array has many such layers with only the top layer being illustrated in FIG. 4C.

FIG. 4C depicts a plurality of circles that represent the memory holes, which are also referred to as vertical columns. Each of the memory holes/vertical columns includes multiple select transistors (also referred to as a select gate or selection gate) and multiple memory cells. In one embodiment, each memory hole/vertical column implements a NAND string. For example, FIG. 4C labels a subset of the memory holes/vertical columns/NAND strings 416, 418, 420, 422, 424, 426, 428, 430, and 432.

FIG. 4C also depicts a set of bit lines 434, including bit lines 436, 438, 440, 442, . . . 444. FIG. 4C shows twenty four bit lines because only a portion of the block is depicted. It is contemplated that more than twenty four bit lines connected to memory holes/vertical columns of the block. Each of the circles representing memory holes/vertical columns has an “x” to indicate its connection to one of the bit lines. For example, bit line 436 is connected to the memory holes/vertical columns 418, 420, 422, 426, and 432. The bit lines 436, 438, 440, 442 also are in electrical communication with all other blocks in a given plane.

The block depicted in FIG. 4C includes a set of isolation regions 446, 448, 450 and 452, which are formed of SiO₂. However, other dielectric materials also can be used. Isolation regions 446, 448, 450, and 452 serve to divide the top layers of the block into five regions. For example, the top layer depicted in FIG. 4C is divided into regions 454, 456, 458, 460, and 462.

In one embodiment, the isolation regions only divide the layers used to implement select gates so that NAND strings in different regions can be independently selected. In one example implementation, a bit line connects to one memory hole/vertical column/NAND string in each of regions 454, 456, 458, 460, and 462. In that implementation, each block has twenty-four rows of active columns and each bit line connects to five rows in each block.

In one embodiment, all of the five memory holes/vertical columns/NAND strings connected to a common bit line are connected to the same set of word lines; therefore, the system uses the drain side selection lines to choose one (or another subset) of the five to be subjected to a memory operation (program, verify, read, and/or erase).

FIG. 4C also shows Line Interconnects LI, which are metal connections to the source line SL from above the memory array. Line Interconnects LI are positioned adjacent regions 454 and 462.

Although FIG. 4C shows each region 454, 456, 458, 460, and 462 as having four rows of memory holes/vertical columns, five regions and twenty four rows of memory holes/vertical columns in a block, those exact numbers are an example implementation. Other embodiments may include more or fewer regions per block; more or fewer rows of memory holes/vertical columns per region; and more or fewer rows of vertical columns per block.

FIG. 4C also shows the memory holes/vertical columns being staggered. In other embodiments, different patterns of staggering can be used. In some embodiments, the memory holes/vertical columns are not staggered.

FIG. 4D depicts a portion of one embodiment of a three dimensional memory structure 202 showing a cross-sectional view along line AA of FIG. 4C. This cross sectional view cuts through memory holes/vertical columns (NAND strings) 428 and 430 of region 462 (see FIG. 4C).

The structure of FIG. 4D includes two drain side select layers SGD0 and SGD1; two source side select layers SGS0 and SGS1; two drain side GIDL generation transistor layers SGDT0 and SGDT1; two source side GIDL generation transistor layers SGSB0 and SGSB1; two drain side dummy word line layers DD0 and DD1; two source side dummy word line layers DS0 and DS1; dummy word line layers DU and DL that are separated by a joint; one hundred and sixty two word line layers WL0-WL161 for connecting to data memory cells; and dielectric layers DL. Other embodiments can implement more or fewer than the numbers described above for FIG. 4D. In one embodiment, SGD0 and SGD1 are connected together and SGS0 and SGS1 are connected together. In other embodiments, more or fewer SGDs (greater or lesser than two) are connected together and more or fewer SGS devices (greater or lesser than two) are connected together.

In one embodiment, erasing the memory cells is performed using gate induced drain leakage (GIDL), which includes generating charge carriers at the GIDL generation transistors such that the carriers get injected into the charge trapping layers of the NAND strings to change (reduce) respective threshold voltages Vt of the memory cells. In the embodiment of FIG. 4D, there are two GIDL generation transistors at each end of the NAND string; however, in other embodiments there are more or fewer than two GIDL generation transistors.

Embodiments that use GIDL at both sides of the NAND string may have GIDL generation transistors at both sides. Embodiments that use GIDL at only the drain side of the NAND string may have GIDL generation transistors only at the drain side. Embodiments that use GIDL at only the source side of the NAND string may have GIDL generation transistors only at the source side.

The GIDL generation transistors have an abrupt PN junction to generate the charge carriers for GIDL and, during fabrication, a phosphorous diffusion is performed at the polysilicon channel of the GIDL generation transistors. In some cases, the GIDL generation transistor with the shallowest phosphorous diffusion is the GIDL generation transistor that generates the charge carriers during erase. However, in some embodiments charge carriers can be generated by GIDL at multiple GIDL generation transistors at a particular side of the NAND string.

The memory holes/vertical columns 428, 430 are depicted protruding through the drain side select layers, source side select layers, dummy word line layers, GIDL generation transistor layers and word line layers. In one embodiment, each memory hole/vertical column comprises a vertical NAND string. Below the memory holes/vertical columns and the layers listed below is substrate 464, an insulating film 466 on the substrate, and source line SL. The NAND string of memory hole/vertical column 428 has a source end at a bottom of the stack and a drain end at a top of the stack. As in agreement with FIG. 4C, FIG. 4D show vertical memory hole/column 428 connected to bit line 442 via connector 468.

For ease of reference, drain side select layers, source side select layers, dummy word line layers, GIDL generation transistor layers and data word line layers collectively are referred to as conductive layers.

In one embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof.

In some embodiments, different conductive layers can be formed from different materials. Between conductive layers are dielectric layers DL. In one embodiment, the dielectric layers are made from SiO₂. In other embodiments, other dielectric materials can be used to form the dielectric layers.

The non-volatile memory cells are formed along memory holes/vertical columns which extend through alternating conductive and dielectric layers in the stack. In one embodiment, the memory cells are arranged in NAND strings. The word line layers WL0-W161 connect to memory cells (also called data memory cells). The dummy word line layers connect to a plurality of dummy memory cells, which do not store data. In some embodiments, the data memory cells and the dummy memory cells may have a same structure. The drain side select layers SGD0 and SGD1 are used to electrically connect and disconnect the NAND strings to and from the bit lines. The source side select layers SGS0 and SGS1 are used to electrically connect and disconnect the NAND strings to and from the source line SL.

FIG. 4D shows that the memory array is implemented as a two tier architecture, with the tiers separated by a joint area. In one embodiment, it is expensive and/or challenging to etch so many word line layers intermixed with dielectric layers. To ease this burden, a first stack of word line layers (e.g., WL0-WL80) are laid down with alternating dielectric layers, then the Joint area is laid down, and next, a second stack of word line layers (e.g., WL81-WL161) are laid down with alternating dielectric layers. The joint area is thus positioned between the first stack of word line layers and the second stack of word line layers. In one embodiment, the joint areas are made from the same materials as the word line layers. In other embodiments, there can no joint area or there can be multiple joint areas.

FIG. 4E depicts a portion of one embodiment of a three dimensional memory structure 202 showing a cross-sectional view along line BB of FIG. 4C. This cross sectional view cuts through memory holes/vertical columns (NAND strings) 416 and 470 of region 454 (see FIG. 4C). FIG. 4E shows the same alternating conductive and dielectric layers as FIG. 4D.

FIG. 4E also shows isolation region 446, which occupies a space that would have been used for a portion of the memory holes/vertical columns/NAND stings, including a space that would have been used for a portion of memory hole/vertical column 470. More specifically, a portion (e.g., half the diameter) of vertical column 470 has been removed in layers SGDT0, SGDT1, SGD0, and SGD1 to accommodate isolation region 446. Thus, while most of the vertical column 470 is cylindrical (has a circular cross section), the portion of vertical column 470 in layers SGDT0, SGDT1, SGD0, and SGD1 has a semi-circular cross section. In one embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 454, 456, 458, 460, and 462 (illustrated in FIG. 4C).

FIG. 4F depicts a cross sectional view of region 472 of FIG. 4D that includes a portion of memory hole/vertical column 428. In one embodiment, the memory holes/vertical columns are round. However, in other embodiments other shapes can be used. In one embodiment, memory hole/vertical column 428 includes an inner core layer 474 that is made of a dielectric, such as SiO₂. Surrounding the inner core 474 is a polysilicon channel 476 (materials other than polysilicon can alternately be used). The channel 476 extends between and is connected with the bit line and the source line. Surrounding the channel 476 is a tunneling dielectric 478 layer, which may have an ONO structure. Surrounding the tunneling dielectric 478 layer is charge trapping layer 480, which may be formed of, for example, Silicon Nitride. It should be appreciated that the technology described herein is not limited to any particular material or structure.

FIG. 4F depicts the dielectric layers DL as well as the word line layers WL160, WL159, WL158, WL157, and WL156. Each of these word line layers includes a word line region 482 surrounded by an aluminum oxide layer 484, which is surrounded by a blocking oxide layer 486. In other embodiments, the blocking oxide layer 486 can be a vertical layer that is parallel with and adjacent to the charge trapping layer 480. The physical interaction of the word line layers with the vertical column forms the memory cells of the NAND string. Thus, in one embodiment a memory cell includes the channel 476, the tunneling dielectric 478, the charge trapping layer 480, the blocking oxide layer 486, the aluminum oxide layer 484, and the word line region 482. For example, word line layer WL160 and a portion of memory hole/vertical column 428 comprise a memory cell MC1. Word line layer WL159 and a portion of memory hole/vertical column 428 comprise a memory cell MC2. Word line layer WL158 and a portion of memory hole/vertical column 428 comprise a memory cell MC3. Word line layer WL157 and a portion of memory hole/vertical column 428 comprise a memory cell MC4. Word line layer WL156 and a portion of memory hole/vertical column 428 comprise a memory cell MC5. In other architectures, a memory cell may have a different structure; however, the memory cell would still be the storage unit.

When a memory cell is programmed, electrons are stored in a portion of the charge trapping layer 480 which is associated with (e.g., in) the memory cell. These electrons are drawn into the charge trapping layer 480 from the channel 476, through the tunneling dielectric 478, in response to an appropriate voltage on word line region 482. The threshold voltage (Vt) of a memory cell is increased in proportion to the amount of stored charge.

In one embodiment, the programming is achieved through Fowler-Nordheim tunneling of the electrons into the charge trapping layer 480. During an erase operation, the electrons return to the channel 476 or holes are injected into the charge trapping layer 480 to recombine with electrons. In one embodiment, erasing is achieved using hole injection into the charge trapping layer 480 via a physical mechanism such as GIDL, as described above.

FIG. 4G is a schematic diagram of a portion of the three dimensional memory array depicted in in FIGS. 4B-4F. FIG. 4G shows physical data word lines WL0-WL161 running across the entire block. The structure of FIG. 4G corresponds to a portion 412 in Block 2 of FIG. 4B, including bit line 436. Within the block, in one embodiment, each bit line is connected to five NAND strings, one in each region of regions 454, 456, 458, 460, 462 (illustrated in FIG. 4C).

In one embodiment, the programming is achieved through Fowler-Nordheim tunneling of the electrons into the charge trapping layer 480. During an erase operation, the electrons return to the channel 476 or holes are injected into the charge trapping layer 480 to recombine with electrons. In one embodiment, erasing is achieved using hole injection into the charge trapping layer 480 via a physical mechanism such as GIDL, as described above.

Similarly, the drain side select line/layer SGD1 is separated by isolation regions 446, 448, 450, and 452 (illustrated in FIG. 4C) to form SGD1-s0, SGD1-s1, SGD1-s2, SGD1-s3 and SGD1-s4 in order to separately connect to and independently control regions 454, 456, 458, 460, 462 (illustrated in FIG. 4C). The drain side GIDL generation transistor control line/layer SGDT0 is also separated by isolation regions 446, 448, 450 and 452 to form SGDT0-s0, SGDT0-s1, SGDT0-s2, SGDT0-s3 and SGDT0-s4 in order to separately connect to and independently control regions 454, 456, 458, 460, 462. Further, the drain side GIDL generation transistor control line/layer SGDT1 is separated by isolation regions 446, 448, 450 and 452 to form SGDT1-s0, SGDT1-s1, SGDT1-s2, SGDT1-s3 and SGDT1-s4 in order to separately connect to and independently control regions 454, 456, 458, 460, 462.

FIG. 4G only shows NAND strings connected to bit line 436. However, a full schematic of the block would show every bit line and five vertical NAND strings, which are in separate regions, connected to each bit line.

Although the example memories of FIGS. 4B-4G are three-dimensional memory structures that include vertical NAND strings with charge-trapping material, other (2D and 3D) memory structures can also be used with the technology described herein.

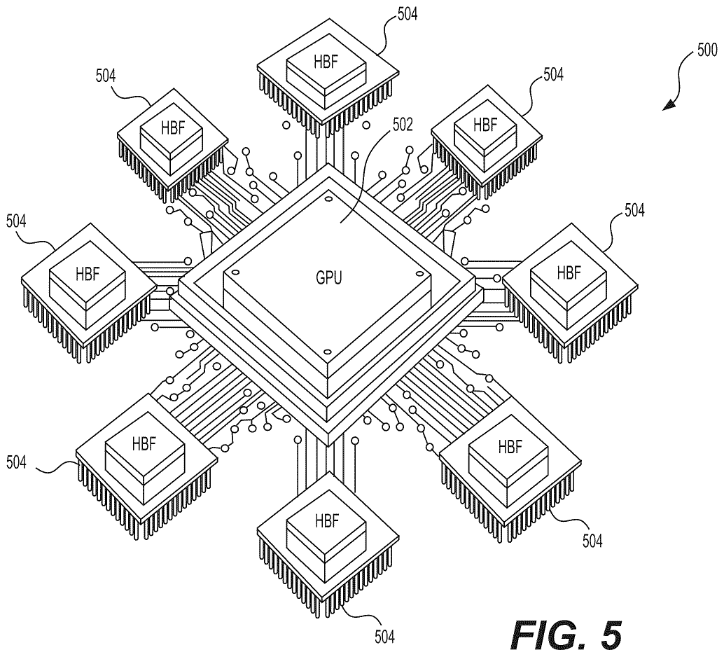

FIG. 5 illustrates an example embodiment of a computing system 500 that is constructed according to aspects of the present disclosure and that is optimized for LLM operations. The computing system 500 includes a single graphics processor unit (GPU) 502 (or a similar processor unit) and eight High Bandwidth Flash (HBF) packages 504, which are all in electrical communication with the single GPU 504. Once the model data (for example, one or more LLM weight matrices) has been stored in the HBF packages 504, the model data is not updated or changed very often. Thus, for a machine learning inferencing application, the HBF packages 504 can be considered write a few times, read many times memory. In some embodiments, the computing system 500 can include more or fewer than eight HBF packages 504. For example, in another embodiment, the computing system includes five HBF packages that are in electrical communication with a single GPU. In some embodiments, the system may also include one or more high bandwidth memory (HBM) packages that may include, for example dynamic random access memory (DRAM).

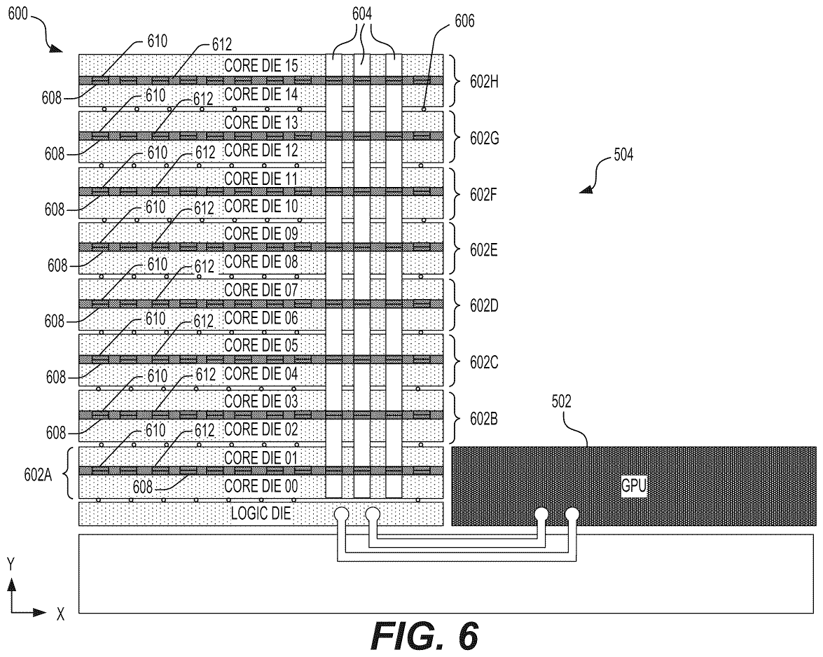

Turning now to FIG. 6, in an exemplary embodiment, each of the HBF packages 504 (or any suitable type of memory package) includes a core memory die stack 600. In the example of FIG. 6, the core memory die stack 600 includes sixteen (16) core memory dies stacked in an arbitrary Y direction, each of which includes 64 planes that can be independently and simultaneously be operated. Each plane includes a plurality of memory blocks. In some embodiments, the number of dies in each HBF packages, the number of planes per die, and the number of memory blocks per plane can vary. The sixteen (16) memory dies (labeled as Core Die 00-15) are arranged in a stacked arrangement and can communicate electronically with the control die or logic die and the GPU 504 by way of the TSVs 604. In some other embodiments, the memory device can have any suitable number of dies that is greater than two, i.e., three or more dies.

Each of the Core Dies 00-15 may have a similar construction. In other words, all sixteen of these dies may have the same number of planes, the same number of memory blocks per plane, the same number of strings per memory block, the same number of word lines per memory block, and the same number of memory cells per word line. Thus, each memory cell in any of the Core Dies has an address (a particular plane/block/string/word line/memory cell combination), and all of the other Core Dies have memory cells with an identical address.

In examples, each Core Die 00-15 comprises a control die 304 bonded to at least one memory die 306, for example, as described above in connection with FIG. 3B. Such a configuration can be referred to as a CMOS Directly Bonded to Array (CBA) Die, for example, where the control die 306 is a CMOS die comprising CMOS technology to implemented control circuitry and logic as described above in connection with FIGS. 2A and 2B.

In some embodiments, adjacent Core Dies may be affixed to each other. For example, as shown in FIG. 6, each memory Core Die 00-15 is affixed (e.g., bonded) to another of Core Die 00-15 forming mirror die pairs (mDiP) 602A-602H (collectively referred to herein as mDiPs 602 or singularly as mDiP 602). A space between two adjacent Core Dies that are bonded together can be filled with a solid layer 612 and bonded via bond pads 608/610, which may be formed from epoxy or other resin or polymer. This solid layer 612 protects the electrical connections between the Core Dies of a respective mDiP and further secures the Core Dies together. Various materials may be used as solid layer 612, but in some embodiments, it may be Hysol epoxy resin from Henkel Corp., having offices in California, USA. Some of the bond pads 608/610 are depicted, although there may be many more bond pads. The solid layer 612 and bond pads 608/610 may be similar to solid layer 312 and bond pads 308/310 of FIG. 3B, respectively.

The core memory die stack 600 may be assembled using micro bumps 606 to affix adjacent mDiPs 602 together. In FIG. 6, micro bump 606 is labeled as an illustrative example of the numerous micro bumps that may be utilized to assemble the HBF package 504. A micro bump may be provided, for example, as a solder ball optionally affixed between contact pads on surfaces of adjacent mDiPs 602. For example, mDiP 602H can be affixed to mDiP 602G via micro bump 606, which comprise a contact pad (e.g., similar to contact pads 322) on a lower surface of Core Die 14, a similar contact pad on upper surface of Core Die 13, and a solder ball (e.g., similar to solder ball 320) sandwiched therebetween.

TSVs 604 may be used to route control and power signals through each Core Die 00-15. The TSVs 604 may be implemented as TSVs 316, TSVs 318, or combinations thereof. In some embodiments, bonds 608/610 may function as connectors through which signals can be routed within a respective mDiP 602. For example, referring to mDiP 602H as an illustrative example, a TSV 604 formed in Core Die 15 can be connected to a TSV 604 formed in Core Die 14 through bonds 608/610 that connect Core Die 15 to Core Die 14. The bonds 608/610 may be aligned with the respective TSVs 604 to provide an electrical connection therebetween. In some embodiments, micro bumps 606 may function as connectors through which signals can be routed between mDiPs 602. For example, a TSV 604 from mDiP 602H can be connected to a TSV 604 of mDiP 602G Core Die 14 through one or more micro bumps that connect mDiP 602H to mDiP 602G. The one or more micro bumps may be aligned with the respective TSVs 604 to provide an electrical connection therebetween.

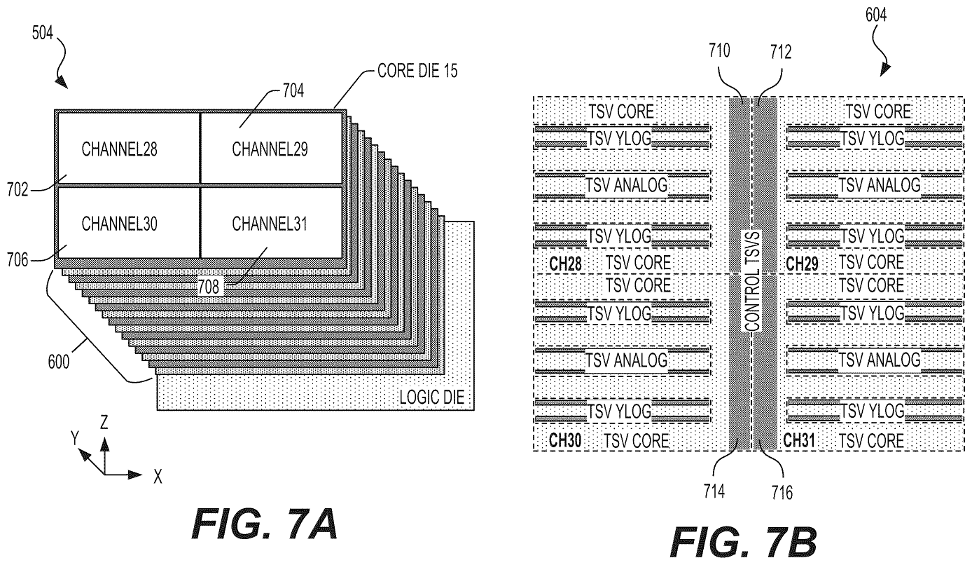

Turning now to FIG. 7A, in an exemplary embodiment, FIG. 7A depicts a perspective top down view of a schematic representation of the HBF package 504, where each Core Die 00-15 of the core memory die stack 600 is partitioned into quadrants. The quadrants of a Core Die may be referred to herein as quarter dies. For example, as shown in FIG. 7, Core Die 15, as an illustrative example, is partitioned into four quarter dies 702-708. Each quarter die may be associated with a respective channel that can be utilized to route signals to and from the logic die. As a result, each quarter die can operate on its own command/address and execute respective operations based on signals from the logic die. As described above, each Core Die 00-15 includes 64 planes and, in examples, each quarter die includes 16 planes.

While examples herein are described with reference to quarter dies, the present disclosure is not limited to partitioning into quadrants. Examples may be partitioned into other fractions of the die to provide a plurality of partial dies. For example, each Core Die may be partitioned into two halves, which results in two partial dies that each include respective TSVs. Likewise, each Core Die may be partitioned into more than four parts (e.g., 6 parts), which results in a corresponding number of partial dies that each include respective TSVs.

Returning to the example of FIG. 7A, Core Dies of a respective mDiP 602 may share common channels amongst respective quarter dies. That is, for example, quarter dies of a respective mDiP occupying an area aligned (e.g., stacked) along the Y direction (referred to herein as a quarter die location) of the core memory die stack 600 may a common channel. As an illustrative example, mDiP 602H comprises Core Die 15 partitioned into quarter dies 702-708, which comprises four channels: channel28 (CH28), channel29 (CH29), channel30 (CH30), and channel31 (CH31), respectively. The quarter die 702 of Core Die 15 shares a quarter die location with a corresponding quarter die of Core Die 14 (not shown in FIG. 7A) and thus share a common channel CH28. Likewise, quarter die 704 and the corresponding quarter die of Core Die 14 share CH29, quarter die 706 and the corresponding quarter die of Core Die 14 share CH30, and quarter die 708 and the corresponding quarter die of Core Die 14 share CH31. Extending this configuration to the other mDiPs, mDiP 602G, which comprises Core Die 13 and Core Die 12, comprises channel24 (CH24), channel25 (CH25), channel26 (CH26), and channel27 (CH27); mDiP 602F, which comprises Core Die 11 and Core Die 10, comprises channel20 (CH20), channel21 (CH21), channel22 (CH22), and channel23 (CH23); and so on until mDiP 602A, which comprises channel00 (CH00), channel01 (CH01), channel02 (CH02), and channel03 (CH03).

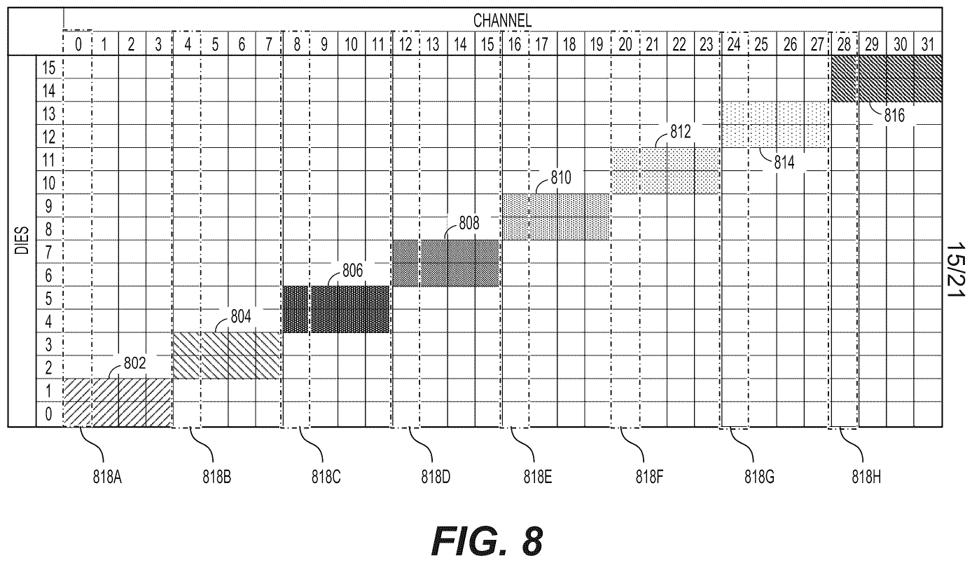

Due to the shared channels, the logic die can control only one quarter die of an mDiP 602 at a given time. For example, logic die can control either quarter die 702 of Core Die 15 or the corresponding quarter die of Core Die 14 via CH28 at a given point in time. FIG. 8 depicts a control scheme for controlling quarter dies of Core Dies 00-15 via respective CH0-CH31. FIG. 8 provides a relationship table that maps CH0-CH31 to respective Core Dies 00-15. Shaded boxes 802-816 maps certain channels to corresponding Core Dies. For example, shaded box 802 depicts that CH0-CH03 correspond to Core Dies 00 and 01 due to shared quarter die location on a respective mDiP 602A. Likewise, shaded box 804 depicts CH04-CH07 correspond to Core Dies 02 and 03; shaded box 806 depicts CH08-CH11 correspond to Core Dies 04 and 05; and so on. As noted above, only one quarter die of a respective mDiP 602 along a given channel can be operated at a given time, and the shaded boxes illustrate this configuration.

FIG. 8 also illustrates shared quarter die locations across the core memory stack 600, which provides that subsets of channels can be grouped into the common quarter die locations. For example, boxes 818A-818H indicate a first subset of channels—CH00, CH04, CH08, CH12, CH16, CH20, CH24, and CH28—share a common quarter die location (e.g., quarter dies overlapping in the Y direction). Likewise, a second subset is provided as CH01, CH05, CH09, CH13, CH17, CH21, CH 25, and CH29; a third subset is provided as CH02, CH06, CH10, CH14, CH18, CH22, CH26, and CH30; and a fourth subset is provided as CH03, CH07, CH11, CH15, CH19, CH23, CH27, and CH31.

Referring now FIG. 7B as an example, TSVs 604 can be located within regions of each respective quarter die, which can be used to form the channels CH00-CH31. For example, FIG. 7B depicts a block diagram of an example configuration of TSVs 604 formed in the Core Die 15. As noted above, Core Die 15 is partitioned into quarter dies 702-708, each of which corresponds to a respective channel CH28-CH31. As shown in FIG. 7B, each channel CH28-CH31 can include a respective control TSV region 710-716, which represents a physical area of the respective quarter die 702-708 in which the TSVs 604 can be located. For example, quarter die 702 comprises control TSV region 710 that can be used to provide CH28, quarter die 704 comprises control TSV region 712 corresponding to CH29, quarter die 706 comprises control TSV region 714 corresponding to CH30, and quarter die 708 comprises control TSV region 716 corresponding to CH31. Also shown in FIG. 7B, are power TSVs for routing power signals to each quarter die (e.g., TSV Core, TSV YLOG, and TSV Analog). FIG. 7B depicts an example configuration of Core Die 15 as an illustrative example and the other Core Dies 00-14 of the core memory die stack 600 may have similar layouts. Furthermore, FIG. 7B provides an illustrative example and other layouts may be utilized as desired.

Each control TSV region 710-716 may comprise the numerous TSVs 604 for routing signals via a respective channel to a respective quarter die 702-704. In examples, the TSVs 604 may be I/O pins used for routing various control signals from the logic die. Example control signal can include data (DQ) control signals, chip select (CS) control signals, command/address (CA) control signals, and clock (CLK) signals. Each control signal may comprise one or more bits. For example, a DQ control signal may comprise eight bits (e.g., DQ[0:7]), a CS control signal may comprise two bits (e.g., CS0/1), a CLK signal may comprise two bits, and a CA control signal may comprise nine bits (e.g., CA[0:8]).

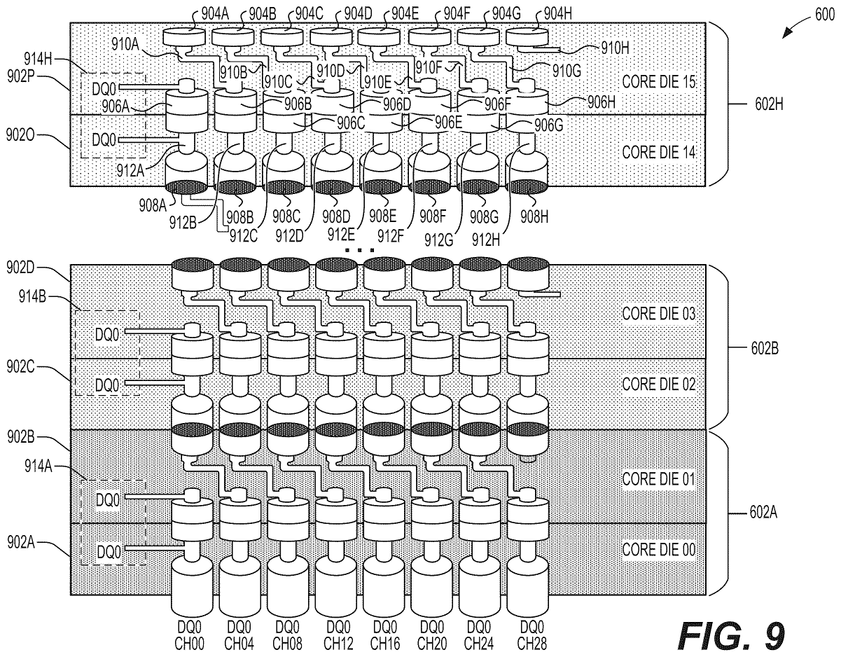

FIG. 9 illustrates a schematic block diagram of cross-sectional view of a portion of the HBF package 504. More particularly, FIG. 9 depicts a cross-sections of example control TSV regions 902A-902P (collectively referred to herein as control TSV regions 902 or singularly as control TSV region 902) of each Core Die 00-15 of core memory die stack 600. For example, control TSV region 902P may be a cross-sectional view of one of control TSV region 710-716 of Core Die 15, described above.

Each control TSV region 902 of a respective mDiP 602 may comprise a substantially similar structure to those of other mDiPs 602. For example, with reference to mDiP 602H as an illustrative example, the control TSV region 902P comprises a plurality of top or first TSVs 904A-904H (collectively referred to herein as first TSVs 904 or singularly as first TSV 904), mDiP connections 906A-906H (collectively referred to herein as mDiP connections 906 or singularly as mDiP connection 906), and bottom or second TSVs 908A-908H (collectively referred to herein as second TSVs 908 or singularly as second TSV 908), each of which may be located at one of a plurality of positions within the control TSV region 900, for example, lateral positions that arranged along a horizontal plane. The Core Dies 14 and 15, in this example, include first routing elements 910A-910H (collectively referred to herein as first routing elements 910 or singularly as first routing element 910) and second routing elements 912A-912H (collectively referred to herein as second routing elements 912 or singularly as second routing element 912) that electrically connect a first TSV 904 to a mDiP connection 906 and a mDiP connection 906 to a second TSV 908, respectively, thereby forming a portion of a channel within the mDiP 602H. In examples, the mDiP connections 906 may comprise bond pads (e.g., bond pads 608/610 described above) that bond two dies together to form the mDiP 602H. The routing elements may be formed by depositing metal interconnects that provide conductive pathways between TSVs.

The first routing elements 910, in the example of FIG. 9, comprise a lateral shift that connects a first TSV 904 at one position to an mDiP connection 906 at a neighboring position (e.g., laterally adjacent position). For example, as shown in FIG. 9, first TSV 904A located at a first position is connected to mDiP connection 906B at a second position via a lateral shift in the first routing element 910A. While FIG. 9 depicts a specific example, in some examples, the lateral shift may be included in the second routing element 912.

As noted above, each mDiP 602 may have the same structure. Accordingly, second TSVs of one mDiP 602 can be connected to first TSVs of an adjacent mDiP 602 of the core memory die stack 600. For example, second TSVs of mDiP 602H can be electrically connected to first TSVs of mDiP 602G (not shown in FIG. 9). The connection between first and second TSVs for adjacent mDiP 602 may be provided via micro bumps (e.g., micro bumps 606) described above.

As a result, a plurality of channels can be provided that span across the core memory die stack 600 along a common quarter die location by connecting second TSVs 908 and first TSVs 904 of adjacent mDiPs 602 and connecting first TSVs 904 to second TSVs 908 within respective mDiPs. In the example of FIG. 9, eight individual channels are formed and located within a common quarter die location, each of which correspond to quarter dies of distinct mDiPs 602. For example, in a case where FIG. 9 depicts a cross-section of a quarter die location corresponding to quarter die 702, the eight channels formed are CH00, CH04, CH08, CH12, CH16, CH20, CH24, and CH28. In this example, CH28 can be used to route signals from the logic die to the mDiP 602H, CH24 can be used to route signals from the logic die to the mDiP 602G, CH20 can be used to route signals from the logic die to the mDiP 602F, and so on. Likewise, if the control TSV regions 902 corresponds to the quarter die location of quarter die 704, the eight channels correspond to CH01, CH05, CH09, CH13, CH17, CH21, CH25, and CH29; if the control TSV regions 902P corresponds to the quarter die location of quarter die 706, the eight channels correspond to CH02, CH06, CH10, CH14, CH18, CH22, CH26, and CH30; and if the control TSV regions 902P corresponds to the quarter die location of quarter die 708, the eight channels correspond to CH03, CH07, CH11, CH15, CH19, CH23, CH27, and CH31.

As alluded to above, TSVs may function as I/O pins for routing various bits of control signals from the logic die, such as DQ control signals, CS control signals, CA control signals, and CLK signals. Each bit of a control signal can be routed to a number of TSV locations 914A-914H on each quarter die based on the number of mDiP 602 in the core memory die stack 600. In the example of FIG. 9, there are eight TSV locations 914A-914H, one per each mDiP 602, due to core memory die stack 600 comprising eight mDiPs 602 and one quarter die per mDiP 602 being controllable at a given time.

Furthermore, each Core Die 00-15 may locally route and connect a single TSV for the same bit of a control signal (e.g., DQ0 bit in this example), while the rest of the TSVs are either unconnected or are part a separate channel connected to at a first lateral position of another mDiP. In examples, each Core Die 00-15 may utilize TSVs at the first position for routing a bit of a control signal. That is, in the example of FIG. 9, a quarter die of Core Dies 14 and 15 may route and connect the DQ0 bit of the DQ control signal using second TSV 908A at the first position, which can be routed to a second TSV of Core Die 00 at the eighth position. Thus, CH28 can be formed between the second TSV 908A in the first position of mDiP 602H to the second TSV 908 at the eight position of mDiP 602A. Likewise, the DQ0 bit can be routed to quarter dies of Core Die 00 and 01 via CH00 connected to a second TSV at a first lateral position in the mDiP 602A. In this example, the remaining TSVs in mDiP 602H are unconnected, whereas the remaining TSVs in mDiP 602A may be utilized as part of channels CH04, CH08, CH12, CH16, CH20, CH24, and CH28 as shown in FIG. 9. Thus, each of the eight channels can be located within the same quarter die location across the core memory die stack 600, as described above herein.

The structure shown in FIG. 9 can be repeated for each bit of each control signal within a respective quarter die location, thereby providing eight channels for each bit within a given quarter die location. Thus, the control TSV region can be repeated numerous times in a respective quarter die to locally route and connect each bit of the control signals and repeated for each respective quarter die to permit each quarter die to operate on its own command/address and execute respective operations. As a result, the core memory die stack 600 can include approximately 12,000 or more TSVs in order to provide for the individual channels for routing control signals accordingly.

HBF packages, such as HBF package 504, can be subject to manufacturing yield concerns. The core dies, such as Core Dies 00-15, have a much larger size compared to conventional memory die, for example, due to the structure that provides for high bandwidth and the low latency operations. As described above, each Core Die 00-15 of the HBF package 504 can include 64 planes compared to four planes of conventional memory dies. Furthermore, each plane in the case of conventional memory dies may be 16 k bytes, whereas, in the case of an HBF package, each plane is 4K bytes. By increasing the die foot-print size, yield and defects (e.g., measured as defective parts per million (DPPM)) concerns may increase.

Yield and defects in the memory array (e.g., die 306 of FIG. 3B) can be addressed through block or column redundancy techniques. However, in an HBF package, the control die (e.g., die 304 of FIG. 3B) is much larger compared to conventional dies and peripheral defects can result in increased yield loss. For example, peripheral circuitry (e.g., CMOS circuitry) can be difficult to replace. A single defective transistor or AND gate can be difficult to locate, let alone replaced. Thus, defects occurring in a control die of an HBF package 504 can result in the entire Core Die becoming unusable, which can significantly increase yield loss.

Additionally, as described above in connection with FIG. 5, HBF packages 504 can be integrated into GPU systems, for example, by connecting multiple HBF packages 504 to a GPU 502. In this case, if one HPG package 504 has a defect resulting in a dead package, the entire GPU system can become defective. Thus, DPPM requirements by computing system manufacturers can be aggressive compared to conventional memory dies because if any of the HBF packages 504 is defective then the whole computing system has to be replaced.

To address the technical short comings described above, the examples herein provide quarter die redundancy and replacement schemes that can be utilized to recover from yield and defect loss. The redundancy and replacement schemes disclosed herein may be implemented during manufacturing, for example, by testing a manufactured memory package (e.g., HBF package) for defects. If a defect is found, the examples herein can be executed to recover the HBF package by replacing the defective die with a redundancy die. Once replaced, the recovered memory package can be installed in computing systems. Additionally, the redundancy and replacement schemes disclosed herein can be utilized in the field to recover installed memory packages. For example, if a defect is detected during use of a memory package (e.g., HBF memory package), the examples disclosed herein can be triggered in real-time to recover a defective die by replacing it with a redundancy die, which can enable continued use of the memory package.

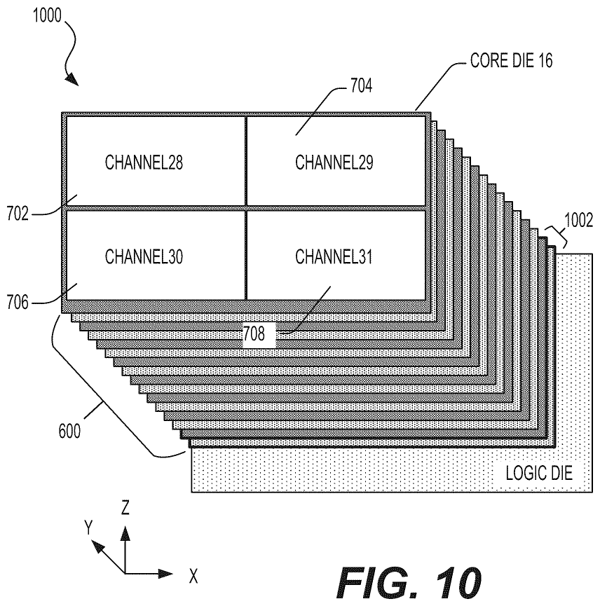

FIG. 10 depicts a schematic view of an example HBF package 1000 that can be used to implement the quarter die replacement and recover schemes according to the examples disclosed herein. HBF package 1000 may be substantially similar to HBF package 504 described above, except that HBF package 1000 comprises an additional redundancy mDiP 1002. In examples, the logic die may be able to detect or otherwise determine that a quarter die is defective and replace the defective quarter die with a redundancy quarter die of the redundancy mDiP 1002.

In examples, the HBF package 1000 includes the core memory die stack 600, including Core Dies 00-15 bonded to provide mDiP 602, and a redundancy mDiP 1002. The redundancy mDiP 1002 may comprise two or more Redundancy Core Dies affixed together in a manner that is substantially similar to the mDiPs 602, as described above. In some examples, each Redundancy Core Die may comprise a control die 304 bonded to at least one memory die 306. In other examples, each Redundancy Core Die need not include any memory dies and may comprise only a control die 304. As shown in FIG. 10, the redundancy mDiP 1002 may be affixed between the core memory die stack 600 and the logic die. However, in other examples, the redundancy mDiP 1002 may be provided elsewhere in the HBF package 504, for example, on top of the core memory die stack 600 or within the core memory die stack 600 between two adjacent mDiPs 602.

As with the Core Dies 00-15, the Redundancy Core Dies of redundancy mDiP 1002 can be partitioned into redundancy quarter dies (also referred to as redundancy partial dies). The redundancy quarter dies may be located the quarter die locations by overlapping in the shared area. As such, the redundancy quarter dies may share channels with the quarter dies of the mDiPs 602 according to common quarter die locations, as described above. For example, a first Redundancy Core Die (RD00) of the mDiP 1002 may be partitioned into four redundancy quarter dies, each having a control TSV region similar to control TSV regions 710-716. A second Redundancy Core Die (RD01) may likewise be partitioned into four redundancy quarter dies. The redundancy quarter dies of RD00 and RD01 share quarter die locations with the quarter dies of the mDiPs 602. The redundancy quarter dies also share respective redundancy channels, which expands the total number of channels by four, in this example. Thus, the redundancy mDiP 1002 may correspond to channel32 (CH32), channel33 (CH33), channel34 (CH34), and channel35 (CH35), which may be used by the redundancy quarter dies to operate on its own command/address and execute respective operations based on signals from the logic die.

In examples, upon detecting a defective quarter die within the core memory die stack 600, the logic die can send a command signal to trigger replacement of the defective quarter die with a redundancy quarter die of the redundancy mDiP 1002. More particularly, the logic die can transition control signals from a channel corresponding to a defective quarter die to a channel corresponding to a redundancy quarter die on the redundancy mDiP 1002. In examples, the logic die may transition one or more control signals from one or more channels of the defective quarter die to the redundancy quarter die, for example, by disabling the one or more channels of the defective quarter die and rerouting the one or more control signals to one or more channels of the redundancy quarter die. The redundancy quarter die and the defective die may be located within the same quarter die location. The one or more control signals can be rerouted by the logic die according to a mapping of the channels, which may be stored to a storage on the logic die (e.g., storage 232).

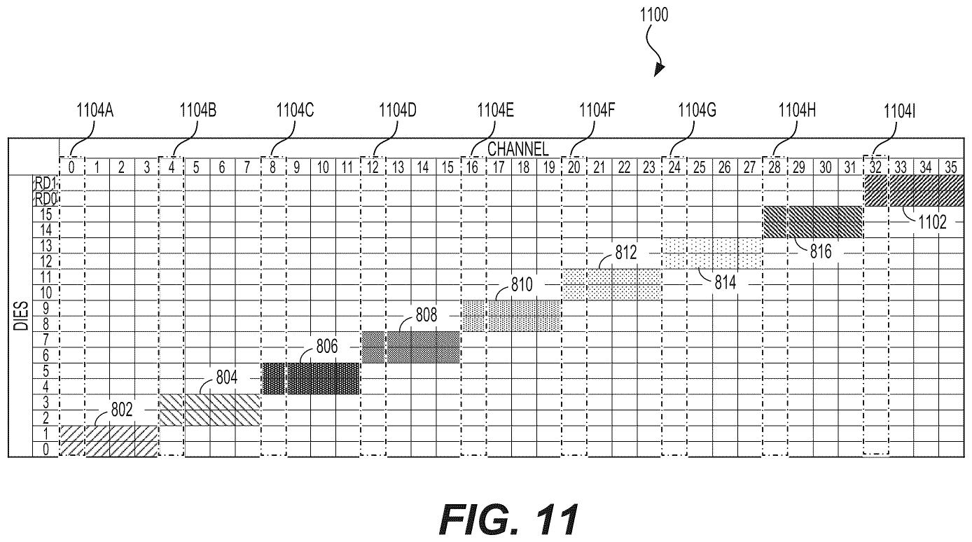

For example, FIG. 11 depicts an example scheme 1100 that can be used to replace defective quarter dies with redundancy quarter dies according to examples of the present disclosure. The scheme 1100 may be an example scheme that maps channels corresponding to each Core Die 00-15 to channels corresponding redundancy dies RD00-01.

FIG. 11 includes the control scheme of FIG. 8 and adds the Redundancy Core Dies RD00 and RD01 and redundancy channels CH32-CH35 (e.g., shaded box 1102). As shown by boxes 1104A-1104I, the boxed subset of channels—CH00, CH04, CH08, CH12, CH16, CH20, CH24, CH28, and CH32—each share a common quarter die location across the HBF package 1000. Due to the shared quarter die location, for a given bit of a control signal, CH32 can be used to replace any one of CH00, CH04, CH08, CH12, CH16, CH20, CH24, or CH28. That is, for example, redundancy quarter dies of RD00 and RD01 corresponding to CH32 can be used to replace quarter dies corresponding CH00, CH04, CH08, CH12, CH16, CH20, CH24, or CH28. In examples, CH32 may be used to replace only one of the channels that share a common quarter die location. Likewise, CH33 can be used to replace any one of CH01, CH05, CH09, CH13, CH17, CH21, CH25, or CH29; CH34 can be used to replace any one of CH02, CH06, CH10, CH14, CH18, CH22, CH26, or CH30; and CH35 can be used to replace any one of CH03, CH07, CH11, CH15, CH19, CH23, CH27, or CH31.

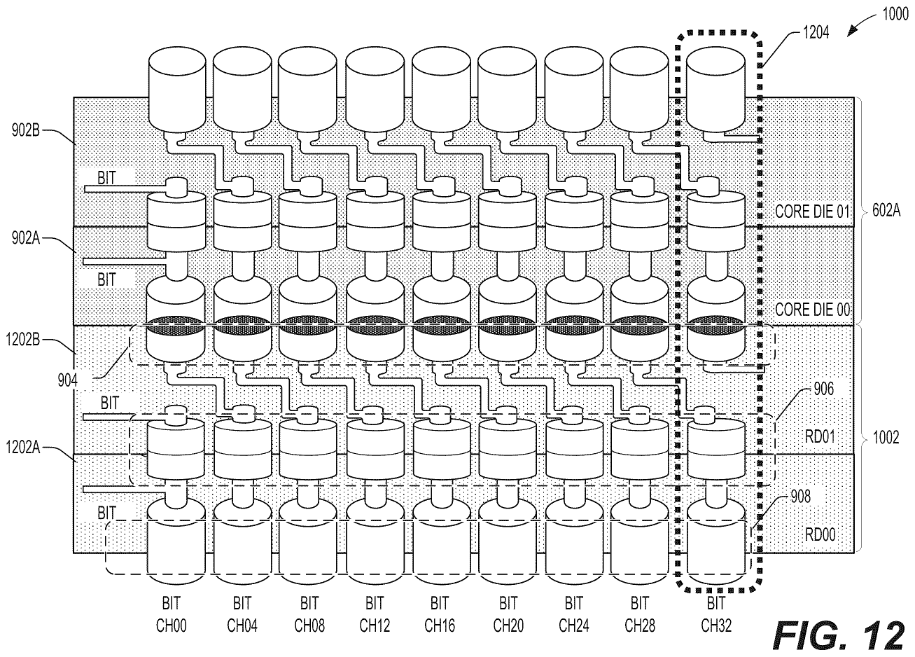

To provide for routing and control of the additional channels and redundancy dies, an additional position (sometimes referred to herein as a redundancy position) can be provide within control TSV regions. For example, FIG. 12 illustrates a schematic block diagram of a portion of the HBF package 1000. FIG. 12 illustrates a cross-sections of an example control TSV regions 902A and 902B of the HFB package 1000 corresponding to mDiP 602A, as described above. Additionally, control TSV regions 1202A and 1202B of redundancy mDiP 1002 are also shown. The other mDiPs 602B-602H are not shown in FIG. 12 for legibility but comprise similar configuration to that of mDiP 602A.

Each control TSV region 902/1202 may comprise a substantially similar structure, as described above, expect that an additional redundancy position 1204 is added to each control TSV region 902/1202. The redundancy position 1204 may be configured to provide additional TSVs to enable the redundancy channel within the quarter die location. Accordingly, a bit of a control signal (shown in FIG. 12 as a “bit”) can be routed to a Core Die 00-15 via one of CH00, CH04, CH08, CH12, CH16, CH20, CH24, and CH28 as described above. However, if the logic die detects a defective quarter die on one CH00, CH04, CH08, CH12, CH16, CH20, CH24, and CH28, the logic die may disable control operations for the channel corresponding to the defective quarter die and reroute the control operations to the CH32 in the same quarter die location.

In some examples, the redundancy and replacement control scheme described in connection with FIGS. 10-12 can be used to replace channels used to route any control signal to a defective die. For example, the bit on the channels in FIG. 12 may be a bit of a DQ control signal (e.g., any one of DQ[0:7], a bit of the CS control signal, a bit of the CA control signal (e.g., any one of CA[0:8]), or a bit of a CLK signal, as well as any other control signals. In this case, the structure of FIG. 12 may be repeated for each bit of each control signal and the control scheme can be utilized to replace defect quarter dies regardless of which type of control signal being routed. For example, upon detecting a defective quarter die, the logic die may disable all control signals for the defective quarter die and route all further operations to the channel of the redundancy quarter die.

This example can provide for a clean and simple control scheme since all replacements can utilize similar logic. Additionally, the redundancy mDiP 1002 can be formed using the same mask design and processes as the mDiPs 602. However, replicating the structure for each bit of each control signal across four quarter dies can increase the number of additional TSVs needed in the core memory die stack, each of which requires additional on-chip physical space. For example, adding a lateral position of FIG. 12 for each control signal may require 256 additional TSVs for the bits of the DQ control signal, two TSVs for the bits of the CLK signal, nine TSVs for the CA control signal, and two TSVs for the CS control signal, which translates to 269 additional TSVs per quarter die (e.g., 1,076 additional TSVs). Additional space may be needed on the die to accommodate the additional TSVs.

In another example, the redundancy and replacement control scheme described in connection with FIGS. 10-12 can be used to replace channels routing CA, CS, and/or CLK control signals to a defective die. For example, the bit on the channels in FIG. 12 may be a bit of the CS control signal, a bit of the CA control signal, or a bit of the CLK signal. In this case, the structure of FIG. 12 may be repeated for each bit of the CA, CS, CLK control signals and a common control scheme can be utilized dependent on the type of control signal being routed. The control scheme for bits of the CA, CS, and CLK signals may be substantially similar to that described in connection with FIGS. 10-12, and DQ control signals may be routed through the original channels designated for DQ control. This example results in fewer additional TSVs (e.g., 9 TSVs for the CA control signals, 2 TSVs for the CLK signal, and 2 TSVs for the CS control signal totaling 13 additional TSV per channel or 52 additional TSVs).

In the above example, a different control scheme can be used to route DQ control signals through the original channels. In this case, TSVs of the RD00 and RD01 can be connected to the original DQ channels through a switching circuit that can toggle the TSVs between a bypass mode and replacement mode. By connecting the TSVs of the RD00 and RD01 to the original channels, contentions may occur, for example, in a case where both an mDiP 602 and the redundancy mDiP 1002 are holding onto the same channel control. Accordingly, each TSV of the redundancy mDiP 1002 can be individually operated to replace a quarter die connected to the respective TSV.

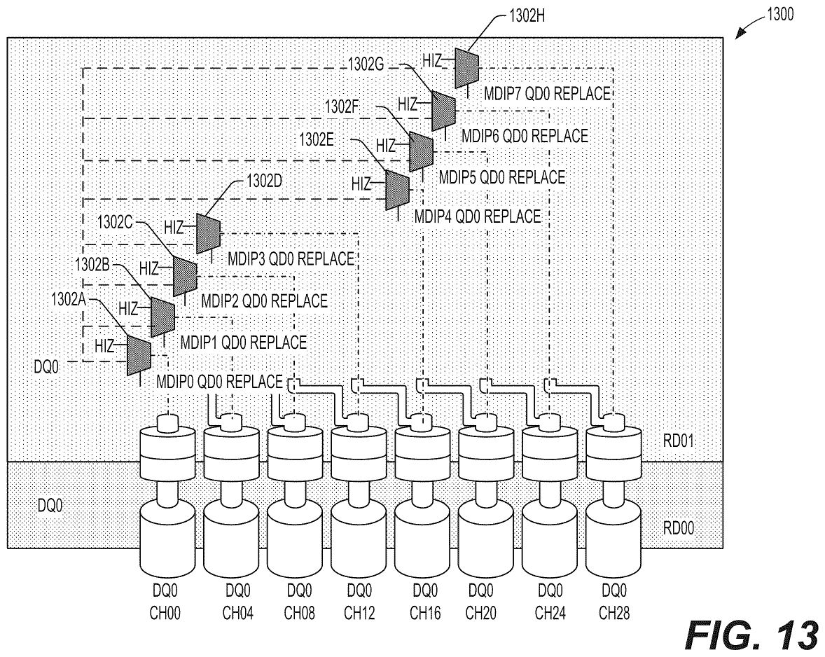

FIG. 13 illustrates a schematic diagram of a redundancy mDiP that may be implemented to route control signals through original channels, in accordance with an example of the present disclosure. Referring to the above example, FIG. 13 may be used to route DQ control signals over the original DQ channels.

FIG. 13 depicts an example redundancy mDiP 1300 (e.g., an example implementation of redundancy mDiP 1002), which comprises a structure substantially similar to the mDiPs 602, as described above in connection with FIG. 9, except that each TSV 908 is connected to one of switching circuits 1302A-1302H (collectively referred to herein as switching circuits 1302 or singularly as switching circuit 1302) via a respective mDiP connection 906. The switching circuits 1302 may be configured to control operation between a bypass mode and a replacement mode. In the bypass mode, the switching circuit 1302 may float, thereby driving a connected DQ channel through the corresponding mDiP 602. In the replacement mode, the switching circuit 1302 can be operated to drive the connected DQ channel through the redundancy mDiP 1300. For example, each switching circuit 1302 comprise a multiplexer that can be driven by the logic die to float (e.g., drive the multiplexer to a high impedance (Z)) or to replace a quarter die connected to a channel corresponding to the respective multiplexer. In the example of FIG. 13, switching circuit 1302A can operated TSV 904 in the first position to replace quarter dies on mDiP 602A at the common quarter die location; switching circuit 1302B can be operated TSV 904 in the first position to replace quarter dies on mDiP 602B at the common quarter die location; switching circuit 1302C can be operated TSV 904 in the first position to replace quarter dies on mDiP 602C at the common quarter die location; and so on. Each DQ channel can be replaced using a respective TSV position on the redundancy mDiP 1300.

FIG. 13 depicts the switching circuits 1302 on RD01 for illustrative purposes. In examples, while not shown in FIG. 13, the switching circuits 1302 can be mimicked on the RD00. For example, switching circuits can be connected to the TSVs 908 within RD00 to provide for controlling the DQ channels from the RD00.

FIG. 13 also illustrates a portion of the redundancy mDiP 1300 for the DQ0 bit channel for illustrative purposes. The structures shown in FIG. 13 can be repeated for each bit of the DQ channel control signals. Thus, the mDiP 1300 may comprise 1,024 multiplexers (e.g., 256 multiplexers for each DQ bit per quarter die).

In operation, if there are no defective quarter dies, the logic die may drive the switching circuits 1302 at high impedance to place the TSVs 908 in bypass mode. Upon detecting a defective quarter die, for example, a quarter die of mDiP 602A corresponding to the quarter die location, the logic die may drive the switching circuit 1302A to replace the defective quarter die on mDiP 602A with the TSV 904 on CH0 by driving the DQ0 bit on CH0 using the redundancy mDiP 1300. However, the redundancy mDiP 1300 cannot just connect to the first TSV position, it has to connect to all eight TSV positions. Thus, the switching circuit 1302 can be controlled to individually replace a given quarter die, for example, by driving the remaining switching circuit 1302 at high impedance in this example.

To control the switching circuits 1302, a protocol can be defined that operates the redundancy mDiP 1300 to identify which mDiPs 602 are to be replaced and drive the corresponding TSV position. In an illustrative example, the protocol may define a replacement control signal, which includes a command and address (e.g., address 0-7 corresponding to mDiP 602A-602H) that can be decoded by the switching circuit 1302 to identify a quarter die to be replaced. The command may instruct the redundancy mDiP 1300 to replace a specified quarter die followed by an address of the mDiP comprising the specified quarter die. A specific quarter die address may not be necessary since the only quarter dies that can be replaced by a given redundancy die are those in the shared quarter location. As such, specifying the mDiP on a specific channel also identifies the quarter die to be replaced. For example, the logic die may send a command to initiate quarter die replacement at address 0 (e.g., mDiP 602A) to the redundancy mDiP 1302. The redundancy mDiP 1302 decodes the command address and enables the switching circuit 1302A corresponding to the decoded address, which drives the TSV at the first position (e.g., connected to CH0). The rest of the switching circuit 1302B-1302H are driving at high impedance, which floats the multiplexers, and permit the mDiPs 602B-602H to drive the respective DQ control channels. The same command and address can disable the mDiP 602A, comprising the defective quarter die, to avoid contentions with the redundancy mDiP 1300 on CH0.

In yet another example, the number of additional TSVs utilized can be reduced by leveraging the X1 mode. The X1 mode is a test mode that comprises a single I/O connection that can route a single bit at a time. In X1 mode, each bit is serialized using a clock (i.e., SKnx clock) and these are the only two controls signals of the X1 mode. In examples, the X1 mode can be used to trigger the replacement by encoding the replacement control signal (e.g., the command/address signals that identifies a defective quarter die and triggers replacement) by encoding the command and address into serialized bits at each clock cycle. An entire replacement control signal may take 11 clock cycles to encoded, for example, the first clock cycle can be used to clock in a start bit, a second cycle can read in an interface bit, the third and fourth bits can read in chip select bits, the fifth bit can define the mode kind of mode, and so one. The X1 protocol can include the command to trigger replacement and an address to identify the mDiP being replaced.

In this example, the redundancy mDiP 1002 of FIG. 10 can include additional channels for the X1 mode only. The additional channels can be used to replace defective channels for communicating the replacement control signal. Thus, for example, the bit on the channels in FIG. 12 may be a bit of the X1 mode that can be used to trigger the replacement control scheme by serializing the command/address in X1 mode bits to replace a quarter die.

Once the replacement control command is decoded in the X1 mode, the original channels can be utilized as replacement, for example, in a manner similar to that described above in connection with FIG. 13. In this example, each of CA, DQ, CS, and CLK signals can be routed over the original channels in a manner described in connection with FIG. 13, where the structure of FIG. 13 is repeated for each bit of each control signal channel. For example, once all the information is accumulated by the X1 mode, the information can be decoded and used to operate the switching circuits 1302 according to the type of channel control signals to be routed.

In the above example, by leveraging the X1 mode, the number of additional TSVs can be reduced to 32 additional TSVs (e.g., 4 X1 TSVs and 4 SKnx TSVs per quarter die). However, the number of multiplexers is increased to 1,076 (e.g., 256 multiplexers for the DQ channel control signals, 9 for the CA channel control signals, 2 for the CLK channel control signals, and 2 for the CS channel control signals per quarter die).

While the above examples provide for redundancy mDiPs, examples herein may utilize a single Redundancy Core Die in place of redundancy mDiP. In this case, the examples herein may operate in a similar manner as described above, but instead of having two Redundancy Core Dies RD00 and RD01 the examples herein may comprise one Redundancy Core Die RD00 that can be used to place defective quarter dies.

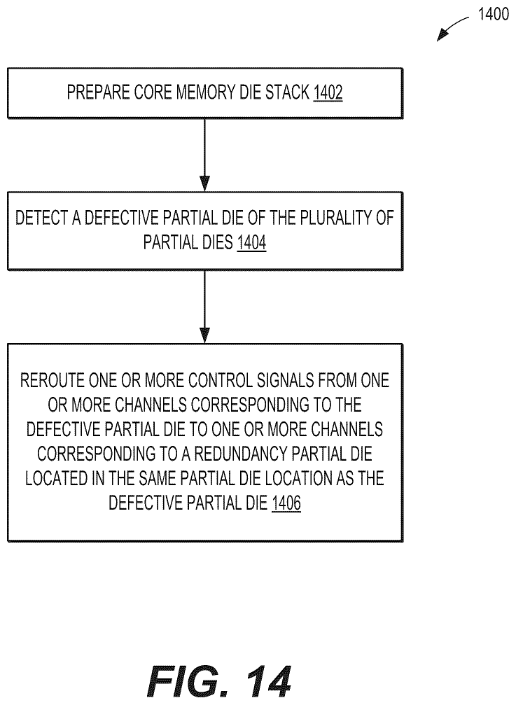

FIG. 14 depicts a flow chart 1400 depicting the steps of performing a quarter die replacement on a core memory die stack according to an embodiment of the present disclosure. These steps could be performed by the controller; a processor or processing device or any other circuitry, executing instructions stored in memory; and/or other circuitry described herein that is specifically configured/programmed to execute the following steps. In examples, the steps may be performed by a logic die as described above.

At step 1402, a core memory die stack can be prepared. In examples, the core memory die stack may include a plurality of core dies partitioned into a plurality of partial dies defining partial die locations. For example, the core memory die stack may be core memory die stack 600 comprising Core Dies 00-15 partitioned into quarter dies. The core memory die stack may also include at least one redundancy die partitioned into a plurality of redundancy partial dies that coincide with the partial die locations. For example, the redundancy die may be provided as two redundancy dies bonded as a redundancy mDiP 1002 or a single redundancy die. The core memory die stack may include a plurality of channels traversing the core memory die stack that route signals to a core die or the redundancy die. For example, the core memory die may include CH00-CH35 as described above.

At step 1404, a defective partial die can be detected. For example, if a quarter die fails program status on multiple blocks across various planes, this could be indicative of a peripheral circuit failure that can kill the whole quarter die. As another example, failure of erase status across multiple blocks on a quarter die may likewise be indicative of a peripheral circuit failure.

At decision step 1406, one or more control signals from one or more channels corresponding to the defective partial die can be rerouted to one or more channels corresponding to a redundancy partial die located in the same partial die location as the defective partial die. For example, the one or more channels corresponding to the defective partial die can be disabled and routed to the one or more channels of the redundancy partial die according to a mapping of channels corresponding to the core dies to channels corresponding to the redundancy die. FIG. 11 depicts an example of such a mapping of channels for an example single bit of control signal.

As described above, the one or more control signals may comprise one or a plurality of control signals to be routed over the one or more channels. That is, in one example, the plurality of control signals comprises CS control signals, CA control signals, and clock signals, while DQ control signals of the defective partial die can be routed over the original DQ channels. In another example, the one or more control signals comprises X1 mode control signals. In yet another example, upon detecting a defective partial die all control signals may be routed over channels of the redundancy partial die.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A memory package, comprising:
a plurality of core dies partitioned into a plurality of partial dies defining partial die locations;
at least one redundancy die partitioned into a plurality of redundancy partial dies, wherein the plurality of redundancy partial dies coincide with the plurality of partial die locations;
a plurality of channels traversing the plurality of core dies and the at least one redundancy die, wherein each channel of the plurality of channels routes signals to a core die of the plurality of core dies or the at least one redundancy die, and wherein subsets of channels of the plurality of channels are located in the partial die locations; and
circuitry for replacing a defective partial die, the circuitry being configured to:
detect that a partial die of the plurality of partial dies is defective; and
reroute a signal from a channel corresponding to the defective partial die to a channel corresponding to a redundancy partial die located in the same partial die location as the defective partial die.

2. The memory package of claim 1, wherein the plurality of core dies comprises control dies having control circuitry for controlling operations on a memory die.

3. The memory package of claim 2, wherein the plurality of core dies comprise a plurality of memory dies bonded to the plurality of core dies, each memory die having a plurality of memory blocks with arrays of memory cells.

4. The memory package of claim 3, wherein the plurality of core dies are comprised as a High Bandwidth Flash memory package.

5. The memory package of claim 1, wherein the plurality of core dies comprises a plurality of mirror die pairs (mDiPs), wherein each mirror die pair comprises a pair of core dies bonded together.

6. The memory package of claim 1, wherein the at least one redundancy die comprises a pair of redundancy dies bonded together.

7. The memory package of claim 1, wherein each of the plurality of core dies and the at least one redundancy die comprises:
a plurality of first through silicon vias (TSVs);
a plurality of second TSVs;
a plurality of routing elements that connect the plurality of the first TSVs to the plurality of the second TSVs; and
a plurality of lateral positions, each comprising one of the first TSVs and one of the second TSVs, wherein each routing element connects a first TSV in one of the plurality of lateral positions to a second TSV in an adjacent lateral position,
wherein the plurality of first and second TSVs form the plurality of channels.

8. The memory package of claim 7, wherein a number of first TSVs in the plurality of first TSVs in a respective core die of the plurality of core dies is equal to a number of channels, wherein the number of channels is based on a number of the plurality of core dies and the at least one redundancy die.

9. The memory package of claim 7, wherein the at least one redundancy die comprises:
a plurality of switching circuits connected to the plurality of second TSVs of the at least one redundancy die.

10. A method of operating a memory package, comprising the steps of:
preparing a core memory die stack, the core memory die stack comprising a plurality of core dies partitioned into a plurality of partial dies defining partial die locations, a redundancy die partitioned into a plurality of redundancy partial dies that coincide with the partial die locations, and a plurality of channels traversing the core memory die stack that route signals to a core die or the redundancy die;
detecting a defective partial die of the plurality of partial dies; and
rerouting one or more control signals from one or more channels corresponding to the defective partial die to one or more channels corresponding to a redundancy partial die located in the same partial die location as the defective partial die.

11. The method of claim 10, wherein rerouting the one or more control signals comprises:
disabling the one or more channels corresponding to the defective partial die; and
routing the one or more control signals to the one or more channels of the redundancy partial die.

12. The method of claim 10, wherein rerouting the one or more control signals is based on a mapping of channels corresponding to the plurality of core dies to channels corresponding to the redundancy die.

13. The method of claim 10, wherein the one or more control signals comprises a plurality of control signals routed over the one or more channels, wherein a number of channels in the one or more channels is equal to a number of bits of the one or more control signals.

14. The method of claim 12, wherein the plurality of control signals comprises chip select (CS) control signals, command/address (CA) control signals, and clock signals.

15. The method of claim 12, wherein data (DQ) control signals of the defective partial die are routed over one or more channels corresponding to the defective partial die.

16. The method of claim 13, wherein the plurality of control signals comprises data (DQ) controls signal.

17. The method of claim 10, wherein the one or more control signals comprises X1 mode control signals.

18. A computing system, comprising:
a processing unit;
a plurality of non-volatile memory packages that are in electrical communication with the processing unit; and
at least one of the non-volatile memory packages including:
a plurality of core dies partitioned into a plurality of partial dies defining partial die locations;
at least one redundancy die partitioned into a plurality of redundancy partial dies, wherein the plurality of redundancy partial dies coincide with the partial die locations;
a plurality of channels traversing the plurality of core dies and the at least one redundancy die, wherein each channel of the plurality of channels routes signals to a core die of the plurality of core dies or the at least one redundancy die, and wherein subsets of channels of the plurality of channels are located in the partial die locations; and
circuitry for replacing a defective partial die, the circuitry being configured to:
detect that a partial die of the plurality of partial dies is defective; and
reroute a signal from a channel corresponding to the defective partial die to a channel corresponding to a redundancy partial die located in the same partial die location as the defective partial die.

19. The computing system as set forth in claim 18, wherein the at least one of the non-volatile memory packages is a High Bandwidth Flash memory package.

20. The computing system as set forth in claim 18, wherein rerouting the signal comprises:
disabling the channel corresponding to the defective partial die; and
routing the control signal to the channel of the redundancy partial die.
